(19) United States
(12) Patent Application Publication
(10) Pub. No.: US 2026/0268944 A1
(43) Pub. Date: Sep. 10, 2026

(54) SEMICONDUCTOR STORAGE DEVICE

(71) Applicant: Kioxia Corporation, Tokyo (JP)

(72) Inventors: Shizuka KUTSUKAKE, Kuwana Mie (JP); Ikuya SAIKI, Yokkaichi Mie (JP); Hideo WADA, Yokkaichi Mie (JP)

(73) Assignee: Kioxia Corporation, Tokyo (JP)

(21) Appl. No.: 19/238,679

(22) Filed: Jun. 16, 2025

(30) Foreign Application Priority Data
Mar. 10, 2025 (JP) 2025-037491

(51) Int. Cl. G11C 5/06; G11C 16/04; H01L 23/00; H10B 43/10; H10B 43/27; H10B 43/35; H10D 80/30

(52) U.S. Cl. CPC G11C 5/063; G11C 16/0483; H10B 43/10; H10B 43/27; H10B 43/35; H10D 80/30; H10W 90/792

(57) ABSTRACT

A semiconductor storage device according to the present embodiment includes a plurality of memory planes and a first columnar electrode. The plurality of memory planes each include one or more blocks. The first columnar electrode is provided in a first area and extends in a first direction substantially perpendicular to the memory planes, the first area being part of a plurality of areas between two of the memory planes.

### CROSS REFERENCE TO RELATED APPLICATIONS

This application is based upon and claims the benefit of priority from the prior Japanese Patent Application No. 2025-037491, filed on Mar. 10, 2025, the entire contents of which are incorporated herein by reference.

### FIELD

The embodiments of the present invention relate to a semiconductor storage device.

### BACKGROUND

In a semiconductor storage device, when memory planes are divided, a dummy staircase portion is embedded in an insulating film to dispose a via contact electrode in some cases. However, in such a case, the disposition of the via contact electrode leads to increase in chip area.

### BRIEF DESCRIPTION OF THE DRAWINGS

FIG. 1 is a perspective view exemplarily illustrating a semiconductor storage device according to a first embodiment;

FIG. 2 is a plan view illustrating a stacked body;

FIG. 3 is a cross sectional view illustrating an exemplary memory cell having a three-dimensional structure;

FIG. 4 is a cross sectional view illustrating the exemplary memory cell having a three-dimensional structure;

FIG. 5 is a plan view illustrating an example of the semiconductor storage device according to the first embodiment;

FIG. 6 is a schematic plan view illustrating arrangement of a connection area and memory cell areas;

FIG. 7A is a perspective view schematically illustrating the connection area of blocks;

FIG. 7B is a perspective view schematically illustrating the connection area of blocks;

FIG. 8A is a plan view illustrating some conductive layers in the connection area in more detail;

FIG. 8B is a plan view illustrating some conductive layers in the connection area in more detail;

FIG. 9 is a schematic block diagram illustrating the configuration of a memory die;

FIG. 10 is a schematic circuit diagram illustrating the configuration of part of the memory die;

FIG. 11 is a schematic exploded perspective view illustrating an example of the configuration of the semiconductor storage device according to the first embodiment;

FIG. 12 is a schematic bottom view illustrating an example of the configuration of a chip;

FIG. 13 is a schematic cross sectional view illustrating the configuration of part of the memory die;

FIG. 14 is a schematic cross sectional view illustrating the configuration of part of the memory die;

FIG. 15 is a plan view illustrating an example of the configuration of the chip according to the first embodiment;

FIG. 16 is a plan view illustrating an example of the configuration of the memory cell area and the connection area according to the first embodiment;

FIG. 17 is a cross sectional view illustrating an example of the configuration of the memory cell area and the connection area according to the first embodiment;

FIG. 18 is a cross sectional view illustrating an example of the configuration of the memory cell area and the connection area according to the first embodiment;

FIG. 19 is a plan view illustrating an example of the configuration of the chip according to the first embodiment;

FIG. 20 is a plan view illustrating an example of the configuration of a chip according to a comparative example;

FIG. 21 is a cross sectional view illustrating an example of the configuration of a memory cell area according to a first modification of the first embodiment;

FIG. 22 is a plan view illustrating an example of the configuration of a chip according to the first modification of the first embodiment;

FIG. 23 is a plan view illustrating an example of the configuration of a chip according to a second modification of the first embodiment;

FIG. 24 is a plan view illustrating an example of the configuration of a chip according to a third modification of the first embodiment;

FIG. 25 is a plan view illustrating an example of the configuration of a chip according to a fourth modification of the first embodiment;

FIG. 26 is a plan view illustrating an example of the configuration of a chip according to a fifth modification of the first embodiment;

FIG. 27 is a plan view illustrating an example of the configuration of a chip according to a sixth modification of the first embodiment;

FIG. 28 is a plan view illustrating an example of the configuration of a chip according to a seventh modification of the first embodiment;

FIG. 29 is a plan view illustrating an example of the configuration of a chip according to an eighth modification of the first embodiment;

FIG. 30 is a cross sectional view illustrating an example of the configuration of a memory cell area according to a second embodiment; and

FIG. 31 is a cross sectional view illustrating an example of the configuration of a connection area according to a third embodiment.

### DETAILED DESCRIPTION

Embodiments will now be explained with reference to the accompanying drawings. The present invention is not limited to the embodiments. It should be noted that the drawings are schematic or conceptual, and the relationship between the thickness and the width in each element and the ratio among the dimensions of elements do not necessarily match the actual ones. Even if two or more drawings show the same portion, the dimensions and the ratio of the portion may differ in each drawing. In the present specification and the drawings, elements identical to those described in the foregoing drawings are denoted by like reference characters and detailed explanations thereof are omitted as appropriate.

In the present specification, the term “semiconductor storage device” may refer to a memory die or may refer to a memory system including a controller die, such as a memory chip, a memory card, or a solid state drive (SSD). The term may also refer to a configuration including a host computer, such as a smartphone, a tablet terminal, or a personal computer.

A semiconductor storage device according to the present embodiment includes a plurality of memory planes and a first columnar electrode. The plurality of memory planes each include one or more blocks. The first columnar electrode is provided in a first area that is part of a plurality of areas between two of the memory planes and extends in a first direction substantially perpendicular to the memory planes.

### First Embodiment

### First Example of Configuration of Semiconductor Storage Device

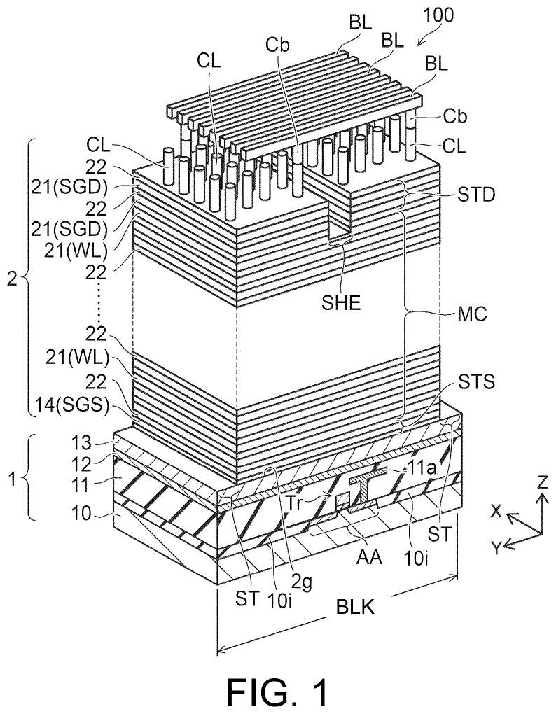

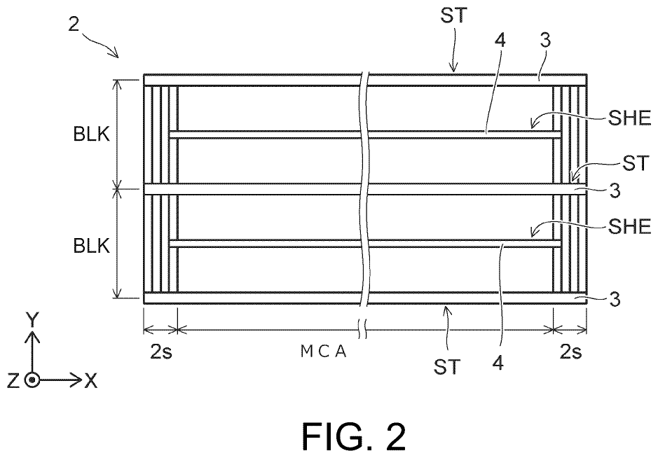

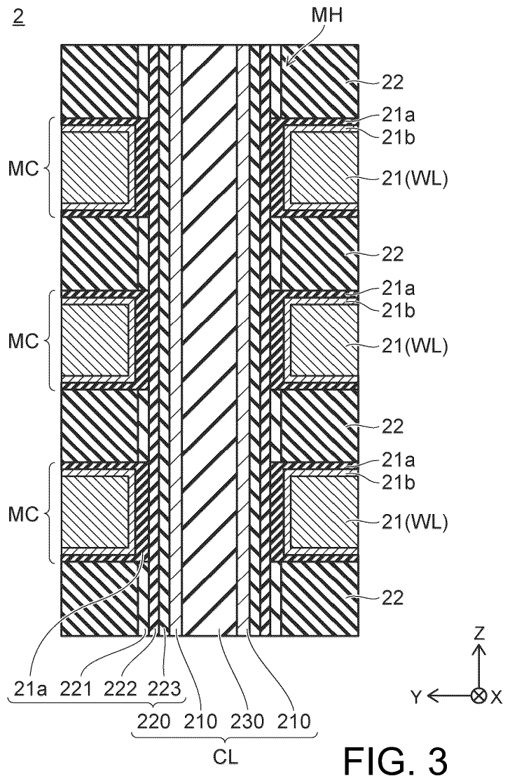

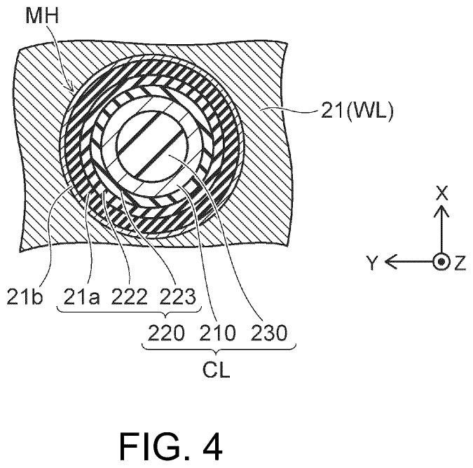

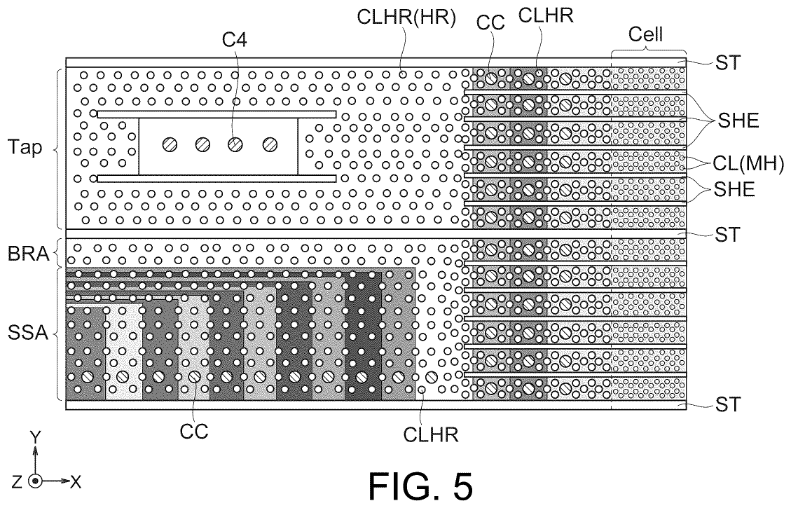

FIG. 1 is a perspective view exemplarily illustrating a semiconductor storage device 100 according to a first embodiment. FIG. 2 is a plan view illustrating a stacked body 2. In the present specification, the stacking direction of the stacked body 2 is defined as a Z-axis direction. One direction orthogonal to the Z-axis direction is defined as a Y-axis direction. A direction orthogonal to the Z-axis and Y-axis directions is defined as an X-axis direction. FIGS. 3 and 4 are cross sectional views illustrating an exemplary memory cell having a three-dimensional structure. FIG. 5 is a plan view illustrating an example of the semiconductor storage device 100 according to the first embodiment. As illustrated in FIGS. 1 to 5, the semiconductor storage device 100 according to the first embodiment is a non-volatile memory including a memory cell array having a three-dimensional structure.

The semiconductor storage device 100 includes a base portion 1, the stacked body 2, a plate-like portion 3, a plurality of columnar portions CL, and a plurality of insulator columns CLHR.

The base portion 1 includes a semiconductor wafer (substrate) 10, an insulating film 11, a conductive film 12, and a semiconductor portion 13. The insulating film 11 is provided on the semiconductor wafer 10. The conductive film 12 is provided on the insulating film 11. The semiconductor portion 13 is provided on the conductive film 12. The semiconductor wafer 10 is, for example, a silicon wafer. The semiconductor wafer 10 has, for example, a p-type conductivity. For example, an element separation area 10i is provided in a surface area of the semiconductor wafer 10. The element separation area 10i is, for example, an insulation area including a silicon oxide film and defines an active area AA in the surface area of the semiconductor wafer 10. The source and drain areas of a transistor Tr are provided in the active area AA. The transistor Tr constitutes a complementary metal oxide semiconductor (CMOS) circuit as a control circuit of a non-volatile memory. The insulating film 11 includes, for example, a silicon oxide film and insulates the transistor Tr. A wiring 11a is provided in the insulating film 11. The wiring 11a is electrically connected to the transistor Tr. The conductive film 12 contains a conductive metal, for example, tungsten (W). The semiconductor portion 13 contains, for example, n-type silicon. Part of the semiconductor portion 13 may include undoped silicon.

The stacked body 2 is positioned above the semiconductor portion 13 in the Z-axis direction. The stacked body 2 is constituted by alternately stacking a plurality of conductive layers 21 as a plurality of first conductive layers and a plurality of insulating layers 22 as a plurality of first insulating layers in the Z-axis direction. The plurality of conductive layers 21 are stacked with an insulating layers 22 interposed therebetween so as to be spaced from each other. The conductive layers 21 contain a conductive metal, for example, tungsten. The insulating layers 22 contain, for example, silicon oxide. The insulating layers 22 insulate the conductive layers 21 from each other. The number of stacked conductive layers 21 and the number of stacked insulating layers 22 are optional. The insulating layers 22 may be, for example, gaps. For example, an insulating film 2g is provided between the stacked body 2 and the semiconductor portion 13. The insulating film 2g includes, for example, a silicon oxide film. The insulating film 2g may contain a high-permittivity dielectric material having a relative permittivity higher than that of silicon oxide. The high-permittivity dielectric material may be, for example, an oxide including a hafnium oxide film.

The conductive layers 21 include at least one source-side selection gate SGS, a plurality of word lines WL, and at least one drain-side selection gate SGD. The source-side selection gate SGS is a gate electrode of a source-side selection transistor STS. Each word line WL is a gate electrode of a memory cell MC. The drain-side selection gate SGD is a gate electrode of a drain-side selection transistor STD. The source-side selection gate SGS is provided in a lower area of the stacked body 2. The drain-side selection gate SGD is provided in an upper area of the stacked body 2. The lower area refers to an area of the stacked body 2 on a side closer to the base portion 1, and the upper area refers to an area of the stacked body 2 on a side farther from the base portion 1. The word lines WL are provided between the source-side selection gate SGS and the drain-side selection gate SGD.

The Z-axis directional thickness of an insulating layer 22 insulating the source-side selection gate SGS from the word lines WL among the plurality of insulating layers 22 may be larger than, for example, the Z-axis directional thickness of an insulating layer 22 insulating the word lines WL from each other. In addition, a cover insulating film may be provided on the uppermost insulating layers 22 farthest from the base portion 1. The cover insulating film contains, for example, silicon oxide.

The semiconductor storage device 100 includes a plurality of memory cells MC connected in series between the source-side selection transistor STS and the drain-side selection transistor STD. A structure in which the source-side selection transistor STS, the memory cells MC, and the drain-side selection transistor STD are connected in series is called “memory string” or “NAND string”. The memory string is connected to, for example, bit lines BL through contacts Cb. The bit lines BL are provided above the stacked body 2 and extend in the Y-axis direction.

A plurality of deep slits ST and a plurality of shallow slits SHE are provided in the stacked body 2. As illustrated in FIG. 2, the slits ST extend in the X-axis direction in planar layout. The slits ST penetrate through the stacked body 2 from the upper end of the stacked body 2 to the base portion 1 at a section in the Z direction (stacking direction) and are provided in the stacked body 2. The plate-like portion 3 in FIG. 2 is provided in each slit ST. For example, an insulating film such as a silicon oxide film is used as the plate-like portion 3. Alternatively, the plate-like portion 3 may be made of a conductive metal such as a conductive material (for example, tungsten or copper), which is electrically connected to the semiconductor portion 13 and may be electrically insulated from the stacked body 2 by an insulating film. The slits SHE extend in the X-axis direction substantially in parallel with the slits ST in planar layout. The slits SHE are provided from the upper end of the stacked body 2 to an intermediate portion of the stacked body 2 at a section in the Z direction. For example, an insulator 4 is provided in each slit SHE. For example, an insulating film such as a silicon oxide film is used as the insulator 4.

As illustrated in FIG. 2, the stacked body 2 includes staircase portions 2s and a memory cell array MCA. Each staircase portion 2s is provided at an edge portion of the stacked body 2. The memory cell array MCA is sandwiched or surrounded by the staircase portions 2s. The slit ST is provided from the staircase portion 2s at one end of the stacked body 2 to the staircase portion 2s at the other end of the stacked body 2 through the memory cell array MCA. The slit SHE is provided at least in the memory cell array MCA. Note that the staircase portions 2s are disposed on both sides of the memory cell array MCA in FIG. 2, but may be disposed on a central side of the memory cell array MCA. In this case as well, staircase portions 2s used dummies may be disposed on both sides of the memory cell array MCA.

A part of the stacked body 2 sandwiched by two slits ST (plate-like portions 3) is referred to as a block BLK. A block constitutes, for example, a minimum unit of data erasure. The slits SHE (insulators 4) are provided in a block. The stacked body 2 between a slit ST and a slit SHE is referred to as a finger. The drain-side selection gate SGD is partitioned for each finger. Accordingly, during data writing and reading, one of the fingers in a block can be brought into a selected state by the drain-side selection gate SGD.

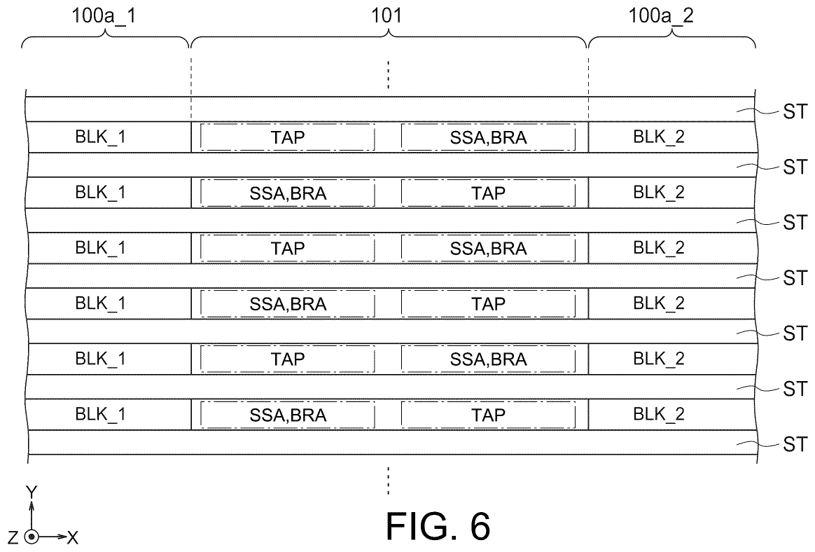

As illustrated in FIG. 5, the memory cell array MCA includes a cell area Cell and other areas. In the cell area Cell, a plurality of columnar portions CL are provided in memory holes MH. The areas other than the cell area Cell include a tap area Tap, a staircase area SSA, and a bridge area BRA. The tap area Tap is provided in a block BLK adjacent to the staircase area SSA and the bridge area BRA in the Y direction with a slit ST interposed therebetween. As illustrated in FIG. 6, the tap area Tap may be provided between cell areas in the X direction. The staircase area SSA and the bridge area BRA may be provided between cell areas in the X direction. The staircase area SSA is an area in which a plurality of contact plugs CC are provided. As illustrated in FIG. 6, the bridge area BRA is provided to electrically connect wiring layers of the word lines WL of a block BLK adjacent thereto in the X direction with the staircase area SSA interposed therebetween. The tap area Tap is an area in which contact plugs C4 are provided. The contact plugs CC and C4 extend in, for example, the Z-axis direction. The contact plugs CC are electrically connected to, for example, the conductive layers 21, respectively. The contact plugs C4 are electrically connected to, for example, the wiring 11a for power supply to the transistor Tr or the like. For example, a low-resistance metal such as copper or tungsten is used as the contact plugs CC and C4.

An insulating film (not illustrated) is provided around each of the contact plugs CC and C4. With this configuration, the contact plugs CC and C4 are electrically insulated from the stacked body 2. Accordingly, while being insulated from the stacked body 2, the contact plugs CC and C4 can electrically connect wirings and the like above the stacked body 2 to wirings and the like below the stacked body 2. For example, an insulating film such as a silicon oxide film is used as the insulating film.

The plurality of columnar portions CL are provided in the respective memory holes MH provided in the stacked body 2. The memory holes MH extend from the upper end of the stacked body 2 into the stacked body 2 and the semiconductor portion 13 through the stacked body 2 in the stacking direction of the stacked body 2 (Z-axis direction). As illustrated in FIGS. 3 and 4, each of the plurality of columnar portions CL includes a semiconductor body 210 as a semiconductor pillar, a memory film 220, and a core layer 230. The semiconductor body 210 extends in the stacking direction (Z direction) in the stacked body 2. The semiconductor body 210 is electrically connected to the semiconductor portion 13. The memory film 220 has a charge trapping portion between the semiconductor body 210 and each conductive layer 21. A plurality of columnar portions CL each selected from a finger are commonly connected to one bit line BL through contacts Cb. Each columnar portion CL is provided in, for example, a cell area (Cell) in FIG. 5.

As illustrated in FIGS. 3 and 4, the shape of each memory hole MH on an X-Y plane is, for example, circle or ellipse. A block insulating film 21a that constitutes part of the memory film 220 may be provided between each conductive layer 21 and the corresponding insulating layer 22. The block insulating film 21a is, for example, a silicon oxide film or a metallic oxide film. One example of the metallic oxide is aluminum oxide. A barrier film 21b may be provided between each conductive layer 21 and the corresponding insulating layer 22 and between each conductive layer 21 and the memory film 220. In a case where the conductive layer 21 is tungsten, for example, the barrier film 21b is selected as a stacked structure film of titanium nitride or titanium. The block insulating film 21a suppresses back tunneling of electric charge from the conductive layer 21 toward the memory film 220. The barrier film 21b improves adhesion between the conductive layer 21 and the block insulating film 21a.

The shape of the semiconductor body 210 is, for example, tubular. The semiconductor body 210 contains, for example, silicon. The silicon is, for example, polysilicon obtained by crystallizing amorphous silicon. The semiconductor body 210 is, for example, undoped silicon. The semiconductor body 210 may be p-type silicon. The semiconductor body 210 serves as a channel for each of the drain-side selection transistor STD, the memory cells MC, and the source-side selection transistor STS.

Part of the memory film 220 other than the block insulating film 21a is provided between the inner wall of the memory hole MH and the semiconductor body 210. The shape of the memory film 220 is, for example, tubular. A plurality of memory cells MC have storage regions between the semiconductor body 210 and the conductive layers 21 as the word lines WL and are stacked in the Z-axis direction. The memory film 220 includes, for example, a cover insulating film 221, a charge trapping film 222, and a tunnel insulating film 223. The semiconductor body 210, the charge trapping film 222, and the tunnel insulating film 223 extend in the Z-axis direction.

The cover insulating film 221 is provided between each insulating layer 22 and the charge trapping film 222. For example, silicon oxide is used as the cover insulating film 221. The cover insulating film 221 is provided to protect the charge trapping film 222 from etching when sacrifice films provided between the insulating layers 22 are replaced with the conductive layers 21 in a manufacturing process. The cover insulating film 221 may be removed from between each conductive layer 21 and the memory film 220 in a replacing process. In this case, as illustrated in FIGS. 3 and 4, for example, the block insulating film 21a is provided between each conductive layer 21 and the charge trapping film 222. The cover insulating film 221 may not be provided in a case where the replacing process is not used to form the conductive layers 21.

The charge trapping film 222 is provided between each block insulating film 21a and the cover insulating film 221, and the tunnel insulating film 223. The charge trapping film 222 contains, for example, silicon nitride and includes trap sites in the film that trap charges. Part of the charge trapping film 222 sandwiched between each conductive layer 21 as a word line WL and the semiconductor body 210 serves as a charge trapping portion and constitutes the storage region of the corresponding memory cell MC. The threshold voltage of the memory cell MC changes in accordance with the presence or absence of electric charge in the charge trapping portion or the amount of charge trapped in the charge trapping portion. Accordingly, the memory cell MC can hold information.

The tunnel insulating film 223 is provided between the semiconductor body 210 and the charge trapping film 222. For example, silicon oxide or combination of silicon oxide and silicon nitride is used as the tunnel insulating film 223. The tunnel insulating film 223 is a potential barrier between the semiconductor body 210 and the charge trapping film 222. For example, when electrons are injected from the semiconductor body 210 into the charge trapping portion (write operation) and when holes are injected from the semiconductor body 210 into the charge trapping portion (erase operation), the electrons and holes pass (tunnel) through the potential barrier of the tunnel insulating film 223.

The core layer 230 fills the inner space of the tubular semiconductor body 210. The shape of the core layer 230 is, for example, columnar. For example, an insulating film such as a silicon oxide film is used as the core layer 230.

Each of the plurality of insulator columns CLHR illustrated in FIG. 5 is provided in a hole HR provided in the stacked body 2. The hole HR is provided in the Z-axis direction from the upper end of the stacked body 2 into the stacked body 2 and the semiconductor portion 13 through the stacked body 2. For example, an insulator such as a silicon oxide film is used as the insulator columns CLHR. Each insulator column CLHR may have the same structure as each columnar portion CL. Each insulator column CLHR is provided in, for example, the tap area Tap, the staircase area SSA, and the bridge area BRA. The insulator columns CLHR function as support members for holding void spaces formed in the staircase area and the tap area when sacrifice films (not illustrated) are replaced with the conductive layers 21 (replacing process). The hole HR of each insulator column CLHR has a radius (width in the X direction or the Y direction) larger than that of the corresponding columnar portion CL.

As illustrated in FIG. 1, the semiconductor storage device 100 further includes a semiconductor portion 14. The semiconductor portion 14 is positioned between the stacked body 2 and the semiconductor portion 13. The semiconductor portion 14 is provided between an insulating layer 22 closest to the semiconductor portion 13 among the insulating layers 22 and the insulating film 2g. The semiconductor portion 14 has, for example, an n-type conductivity. The semiconductor portion 14 functions as, for example, the source-side selection gate SGS.

FIG. 6 is a schematic plan view illustrating arrangement of a connection area 101 and memory cell areas 100a. The memory cell areas 100a include a first memory cell area 100a_1 and a second memory cell area 100a_2 that are adjacent to each other. The first memory cell area 100a_1 and the second memory cell area 100a_2 each include a plurality of blocks BLK. In the Y direction, the plurality of blocks BLK are divided from each other by the slits ST extending in the X direction.

The first memory cell area 100a_1 and the second memory cell area 100a_2 each include the above-described plurality of columnar portions CL (memory holes MH) and include a plurality of three-dimensionally disposed memory cells. The memory cells are formed at intersect points of the plurality of word lines WL and the plurality of columnar portions CL.

For sake of simplicity, each block BLK belonging to the first memory cell area 100a_1 is referred to as a block BLK_1. Each block BLK belonging to the second memory cell area 100a_2 is referred to as a block BLK_2.

The connection area 101 is provided between the first memory cell area 100a_1 and the second memory cell area 100a_2 in the X direction intersecting the Z direction and includes the tap area Tap, the staircase area SSA, and the bridge area BRA for each block BLK. Hereinafter, the staircase area SSA and the bridge area BRA are also referred to as the staircase area SSA or the like.

As described above, the tap area Tap and the staircase area SSA or the like are adjacent to each other in the Y direction with a slit ST interposed therebetween. As illustrated in FIG. 6, the tap area Tap and the staircase area SSA or the like are alternately provided in the Y direction. The tap area Tap and the staircase area SSA or the like are alternately provided in the X direction as well. In other words, the tap area Tap and the staircase area SSA or the like are alternately provided in the Y direction with the slits ST interposed therebetween and are alternately provided between memory areas Cell (for example, blocks BLK_1 and BLK_2) in the X direction.

In the staircase area SSA, the selection gate line (source-side selection gate) SGS and end portions of the plurality of respective word lines WL are stepped in the X direction in order from a lower layer and formed in a staircase shape. In other words, the selection gate line SGS and the plurality of word lines WL in the staircase area SSA each include, at its end portion, a terrace portion (also referred to as staircase, staircase portion, or lead-out portion) that does not overlap a lower wiring layer (conductive layer). The contact plugs CC in FIG. 5 are formed on the respective terrace portions. The selection gate line SGS and the plurality of word lines WL can each have voltage applied thereto separately through the contact plugs CC. In this manner, the staircase area SSA is provided as a terrace area for connecting a plurality of contacts to a plurality of respective conductive layers connected to the selection gate line SGS and the plurality of word lines WL.

Note that, the contact plugs CC are electrically connected to the contact plugs C4 in the tap area in FIG. 5 through upper wirings (not illustrated) and electrically connected to a row decoder provided below the memory cell array through the contact plugs C4. Accordingly, the row decoder can control voltages of the conductive layers 21 (word lines WL) through the contact plugs CC. The diameters of the contact plugs CC and C4 are larger than the diameters of the insulator columns CLHR.

In the bridge area BRA, a plurality of third conductive layers corresponding to the selection gate line SGS and the plurality of word lines WL, respectively, are stacked in the Z direction with intervals therebetween. The third conductive layers electrically connect the conductive layers 21 (selection gate line SGS and plurality of word lines WL) in the first memory cell area 100a_1, respectively, to the conductive layers 21 (selection gate line SGS and plurality of word lines WL) in the second memory cell area 100a_2. Accordingly, the first and second memory cell areas 100a_1 and 100a_2 can function as one memory cell array MCA.

In this manner, since the connection area 101 is disposed at an intermediate portion of the memory cell array MCA, the contact plugs CC are positioned in the middle of wiring of the word lines WL, which can shorten the distances from the contact plugs CC to end portions of the word lines WL. Accordingly, the semiconductor storage device 100 can swiftly supply power to the end portions of the word lines WL through the contact plugs CC, facilitating voltage control of the word lines WL. Moreover, since the memory cell areas 100a_1 and 100a_2 can be disposed on the respective sides of one connection area 101, it is possible to increase the scale (storage capacity) of the memory cell array MCA while maintaining operation speed.

The bridge area BRA has the same stacked body structure as the first and second memory cell areas 100a_1 and 100a_2. Accordingly, the stacked body of the bridge area BRA is constituted by alternately stacking a plurality of conductive layers 21 and a plurality of insulating layers 22 in the Z-axis direction. In other words, the plurality of conductive layers 21 as a plurality of third conductive layers are stacked with an insulating layers 22 interposed therebetween so as to be spaced from each other. As described above, the insulating layers 22 may be air gaps.

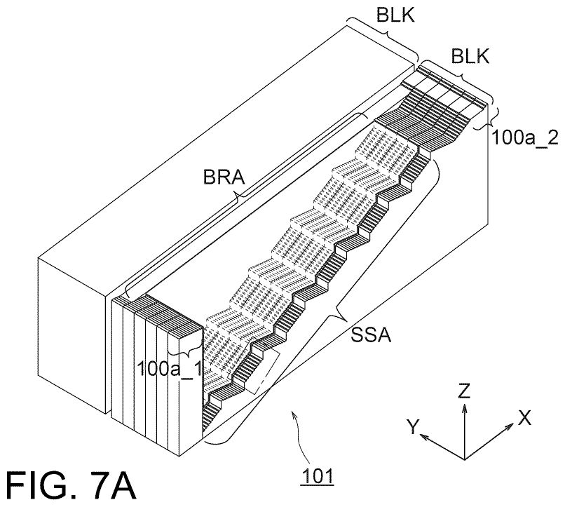

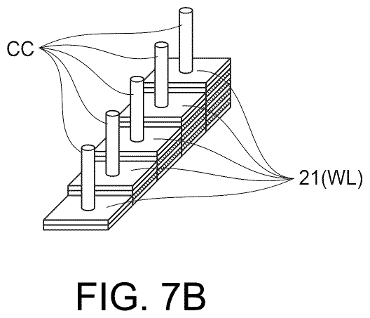

FIGS. 7A and 7B are perspective views schematically illustrating the connection area 101 of a block BLK. In FIGS. 7A and 7B, the tap area Tap is omitted. The staircase area SSA of the connection area 101 is provided in a staircase shape so as to connect the plurality of contact plugs CC to the plurality of conductive layers 21 (word lines WL), respectively. In the bridge area BRA, the plurality of conductive layers 21 electrically connect the conductive layers 21 (word lines WL) between the first and second memory cell areas 100a_1 and 100a_2.

In the connection area 101, the bridge area BRA is provided adjacent to the staircase area SSA in the Y direction (direction substantially orthogonal to the extending direction of the slits ST) and not formed in a staircase shape. Accordingly, the bridge area BRA includes the same number of conductive layers 21 and the same number of insulating layers 22 as in the stacked body 2 in the first and second memory cell areas 100a_1 and 100a_2.

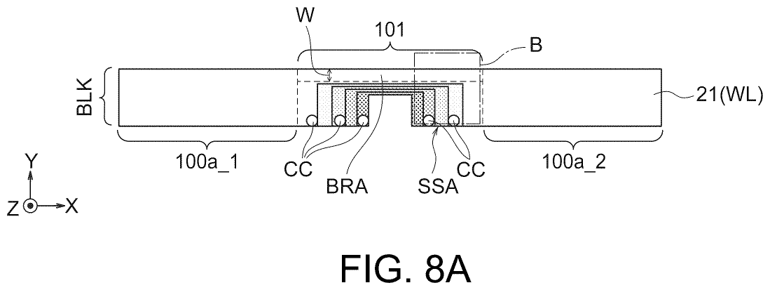

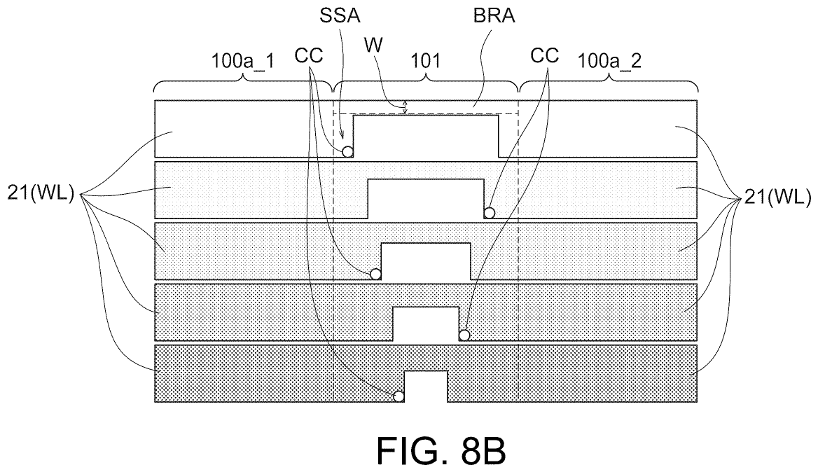

FIGS. 8A and 8B are plan views illustrating some conductive layers 21 in the connection area 101 in more detail. In FIGS. 8A and 8B, the tap area Tap is omitted. FIG. 8A illustrates a state in which the conductive layers 21 are stacked, and FIG. 8B separately illustrates each conductive layer 21. In FIGS. 8A and 8B, five conductive layers 21 are illustrated. The number of the conductive layers 21 of course may be equal to or smaller than four or may be equal to or larger than six. Note that, in FIGS. 8A and 8B, one block BLK portion is illustrated whereas illustration of the columnar portions CL (memory holes MH), the insulator columns CLHR, and the slits SHE in FIG. 5 is omitted. There may be an area in which no conductive layers 21 are formed like a central portion in FIG. 8A.

As illustrated in FIG. 8A, the staircase area SSA of the connection area 101 is formed in a staircase shape such that the surface (tread surface) of each conductive layer 21 is visible in the Z direction. The surface (tread surface) of each conductive layer 21 has a size (area) in which a contact plug CC is connectable in the Z direction. In FIG. 8A, staircase portions in the staircase area SSA are provided on the respective sides of the connection area 101 in the X direction so as to face each other. As illustrated in FIGS. 8A and 8B, one contact plug CC is provided on each conductive layer 21 in the staircase area SSA and connected onto the tread surface of the conductive layer 21. For example, in the example illustrated in FIGS. 8A and 8B, the contact plugs CC are alternately connected to left and right staircase portions in the staircase area SSA. More specifically, a contact plug CC is connected to the tread surface of the uppermost conductive layer 21 at the staircase portion on the left side in the staircase area SSA. A contact plug CC is connected to the tread surface of the second uppermost conductive layer 21 at the staircase portion on the right side in the staircase area SSA. A contact plug CC is connected to the tread surface of the third uppermost conductive layer 21 at the staircase portion on the left side in the staircase area SSA. A contact plug CC is connected to the tread surface of the fourth uppermost conductive layer 21 at the staircase portion on the right side in the staircase area SSA. A contact plug CC is connected to the tread surface of the fifth uppermost (lowermost) conductive layer 21 at the staircase portion on the left side in the staircase area SSA.

Note that, the staircase area SSA may be provided only on one side in the X direction in the connection area 101. In this case, the contact plugs CC are connected to tread surfaces at a staircase portion provided on the one side in the connection area 101.

Since one contact plug CC is provided on each conductive layer 21, the conductive layers 21 in a memory cell area on a side where the contact plugs CC is not connected are electrically connected to the contact plugs CC through the bridge area BRA. For example, no contact plugs CC are provided on the uppermost conductive layer 21 in the second memory cell area 100a_2 on the right side. Thus, the uppermost conductive layer 21 in the second memory cell area 100a_2 on the right side is electrically connected to a contact plug CC provided on the uppermost conductive layer 21 in the second memory cell area 100a_2 on the left side through the uppermost conductive layer 21 in the bridge area BRA. No contact plugs CC are provided on the second uppermost conductive layer 21 in the second memory cell area 100a_2 on the left side. Thus, the second uppermost conductive layer 21 in the second memory cell area 100a_2 on the left side is electrically connected to a contact plug CC provided on the second uppermost conductive layer 21 in the second memory cell area 100a_2 on the right side through the second uppermost conductive layer 21 in the bridge area BRA. In this manner, one of the memory cell areas 100a_1 and 100a_2 on the respective sides of the connection area 101 is electrically connected to the contact plugs CC provided in the other memory cell area through the bridge area BRA.

### Second Example of Configuration of Semiconductor Storage Device Circuit Configuration of Memory Die MD

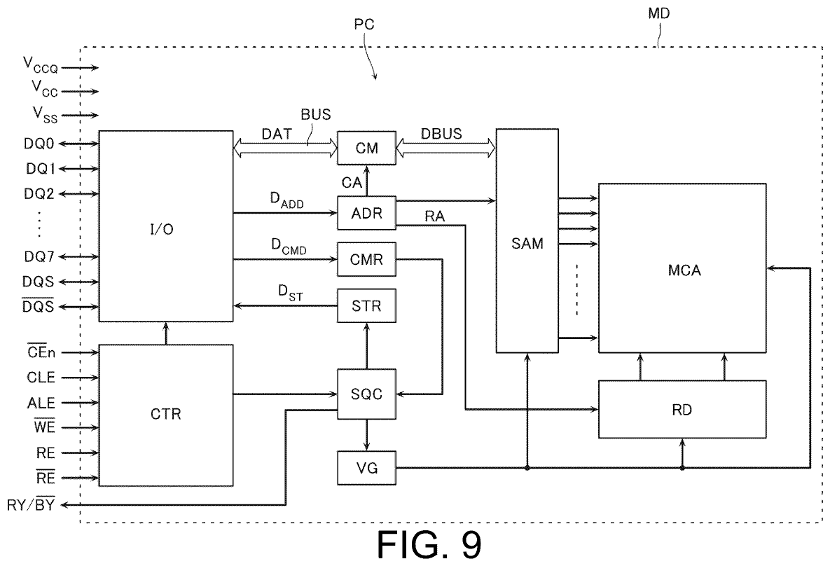

FIG. 9 is a schematic block diagram illustrating the configuration of a memory die MD according to the first embodiment. FIG. 2 is a schematic circuit diagram illustrating the configuration of part of the memory die MD.

Note that FIG. 9 illustrates a plurality of control terminals and the like. The plurality of control terminals may be represented as control terminals corresponding to high-active signals (positive logic signals). The plurality of control terminals may be represented as control terminals corresponding to low-active signals (negative logic signals). The plurality of control terminals may be represented as control terminals corresponding to both high-active and low-active signals. In FIG. 9, the reference sign of a control terminal corresponding to a low-active signal includes an overline (overbar). In the present specification, the reference sign of a control terminal corresponding to a low-active signal includes a slash (“/”). Note that, the illustration in FIG. 9 is exemplary and specific configurations are appropriately adjustable. For example, some or all high-active signals may be low-active signals, and some or all low-active signals may be high-active signals.

As illustrated in FIG. 9, the memory die MD includes the memory cell array MCA and a peripheral circuit PC. The peripheral circuit PC includes a voltage generation circuit VG, a row decoder RD, a sense amplifier module SAM, and a sequencer SQC. The peripheral circuit PC also includes a cache memory CM, an address register ADR, a command register CMR, and a status register STR. The peripheral circuit PC further includes an input-output control circuit I/O and a logic circuit CTR.

### Circuit Configuration of Memory Cell Array MCA

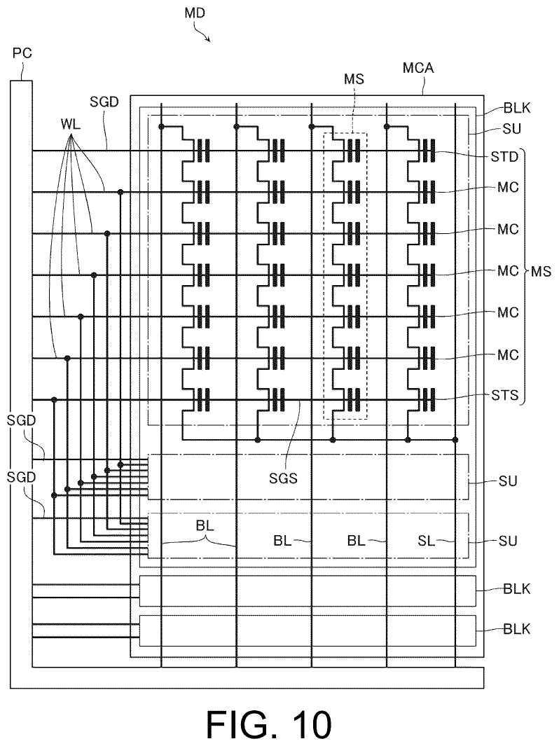

As illustrated in FIG. 10, the memory cell array MCA includes a plurality of memory blocks BLK. The plurality of memory blocks BLK each include a plurality of string units SU. The plurality of string units SU each include a plurality of memory strings MS. One end of each of the plurality of memory strings MS is connected to the peripheral circuit PC through a bit line BL. The other end of each of the plurality of memory strings MS is connected to the peripheral circuit PC through a common source line SL.

Each memory string MS includes the drain-side selection transistor STD, the plurality of memory cells MC (memory transistors), and the source-side selection transistor STS. The drain-side selection transistor STD, the plurality of memory cells MC, and the source-side selection transistor STS are connected in series between the bit line BL and the source line SL. Hereinafter, the drain-side selection transistor STD and the source-side selection transistor STS are also simply referred to as the selection transistor (STD, STS).

Each memory cell MC is a field-effect transistor. Each memory cell MC includes a semiconductor layer, a gate insulating film, and a gate electrode. The semiconductor layer functions as a channel region. The gate insulating film includes a charge accumulation film. The threshold voltage of each memory cell MC changes in accordance with the amount of charge in the charge accumulation film. Each memory cell MC stores data of one bit or a plurality of bits. Note that word lines WL are connected to the gate electrodes of a plurality of memory cells MC, respectively, corresponding to one memory string MS. The word lines WL are each commonly connected to all memory strings MS in one memory block BLK.

The selection transistor (STD, STS) is a field-effect transistor. The selection transistor (STD, STS) includes a semiconductor layer, a gate insulating film, and a gate electrode. The semiconductor layer functions as a channel region. The gate insulating film may include a charge accumulation layer. Selection gate lines (SGD, SGS) are connected to the gate electrode of the selection transistor (STD, STS). One drain-side selection gate line SGD is commonly connected to all memory strings MS in one string unit SU. One source-side selection gate line SGS is commonly connected to all memory strings MS in one memory block BLK. Note that the drain-side selection gate line SGD and the source-side selection gate line SGS are each also referred to as a selection gate line SG.

### Structure of Memory Die MD

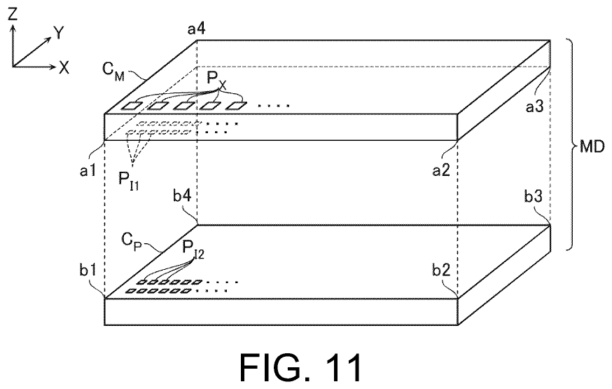

FIG. 11 is a schematic exploded perspective view illustrating an example of the configuration of the semiconductor storage device according to the first embodiment. As illustrated in FIG. 11, the memory die MD includes a chip C_{M} on the memory cell array MCA side, and a chip C_{P} on the peripheral circuit PC side.

A plurality of external pad electrodes P_{X} that are connectable to non-illustrated bonding wires are provided on the upper surface of the chip C_{M}. In addition, a plurality of bonding electrodes P_{I1} are provided on the lower surface of the chip C_{M}. In addition, a plurality of bonding electrodes P_{I2} are provided on the upper surface of the chip C_{P}. Hereinafter, as for the chip C_{M}, a surface on which the plurality of bonding electrodes P_{I1} are provided is referred to as a front surface, and a surface on which the plurality of external pad electrodes P_{X} are provided is referred to as a back surface. As for the chip C_{P}, a surface on which the plurality of bonding electrodes P_{I2} are provided is referred to as a front surface, and a surface opposite the front surface is referred to as a back surface. In the illustrated example, the front surface of the chip C_{P} is provided higher than the back surface of the chip C_{P}, and the back surface of the chip C_{M} is provided higher than the front surface of the chip C_{M}.

The chips C_{M} and C_{P} are disposed such that the front surface of the chip C_{M} and the front surface of the chip C_{P} face each other. The plurality of bonding electrodes P_{I1} are provided in correspondence with the plurality of bonding electrodes P_{I2}, respectively, and disposed at positions where they can be bonded to the plurality of bonding electrodes P_{I2}. The bonding electrodes P_{I1} and P_{I2} function as bonding electrodes for bonding the chips C_{M} and C_{P} in an electrically conducting manner.

Note that, in the example in FIG. 11, corners a1, a2, a3, and a4 of the chip C_{M} correspond to corners b1, b2, b3, and b4 of the chip C_{P}, respectively.

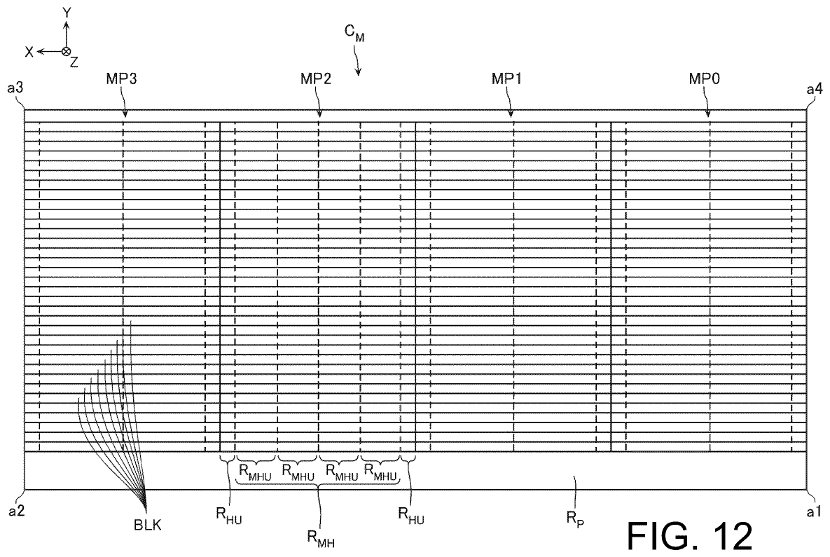

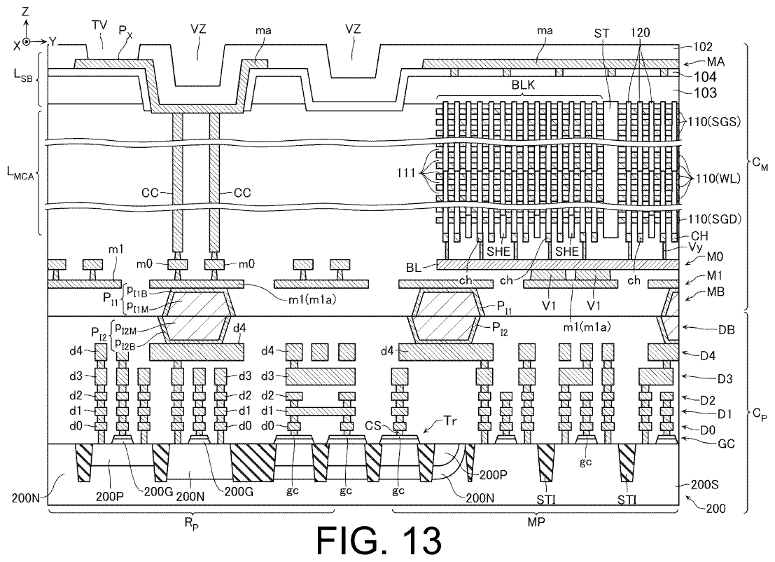

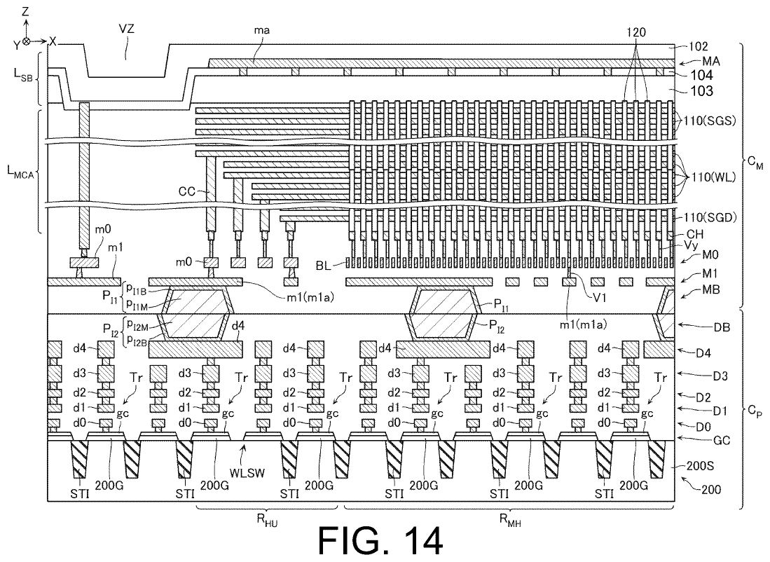

FIG. 12 is a schematic bottom view illustrating an example of the configuration of the chip C_{M}. In FIG. 12, some configurations such as the bonding electrodes P_{I1} are omitted. FIGS. 13 and 14 are schematic cross sectional views illustrating the configuration of part of the memory die MD.

### Structure of Chip C_{M}

In the example in FIG. 12, the chip C_{M} includes four memory planes MP0 to MP3 arranged in the X direction. Note that the four memory planes MP0 to MP3 are each also simply referred to as a memory plane MP. The four memory planes MP0 to MP3 each include a plurality of memory blocks BLK arranged in the Y direction. In the example in FIG. 12, the four memory planes MP0 to MP3 each include hook-up areas R_{HU} provided at both end portions in the X direction, and a memory hole area R_{MH} (memory area) provided between the hook-up areas R_{HU}. In the example in FIG. 12, the memory hole area R_{MH} is divided into four areas R_{MHU} in the X direction. The four areas R_{MHU} may have equal or different widths in the X direction. The chip C_{M} also includes a peripheral area R_{P} provided on one end side of the four memory planes MP0 to MP3 in the Y direction. Each hook-up area R_{HU} corresponds to the connection area 101.

Note that, in the illustrated example, the hook-up areas R_{HU} are provided at both end portions of the memory plane MP in the X direction. However, such a configuration is merely exemplary and specific configurations are appropriately adjustable. For example, the hook-up areas R_{HU} may be provided at one end portion in the X direction, not at both end portions of the memory plane MP in the X direction. Alternatively, the hook-up areas R_{HU} may be provided at the center position of the memory plane MP in the X direction or a position near the center.

As illustrated in FIG. 13, for example, the chip C_{M} includes a base layer L_{SB}, a memory cell array layer L_{MCA} provided below the base layer L_{SB}, a via contact electrode layer CH provided below the memory cell array layer L_{MCA}, a plurality of wiring layers M0 and M1 provided below the via contact electrode layer CH, and a chip bonding electrode layer MB provided below the wiring layers M0 and M1.

### Structure of Base Layer L_{SB} of Chip C_{M}

As illustrated in FIG. 13, for example, the base layer L_{SB} includes a conductive layer 103 provided on the upper surface of the memory cell array layer L_{MCA}, an insulating layer 104 provided on the upper surface of the conductive layer 103, a back-side wiring layer MA provided on the upper surface of the insulating layer 104, and an insulating layer 102 provided on the upper surface of the back-side wiring layer MA.

The conductive layer 103 may include, for example, a semiconductor layer such as silicon (Si) into which an N-type impurity such as phosphorus (P) or a P-type impurity such as boron (B) is injected, may include a metal such as tungsten (W) or aluminum (AL), or may include silicide such as tungsten silicide (WSi).

The conductive layer 103 functions as part of the source line SL (FIG. 9). Four of the conductive layers 103 are provided in correspondence with the four memory planes MP0 to MP3 (FIG. 12). Areas VZ not including the conductive layers 103 are provided at end portions of the memory plane MP in the X and Y direction.

The insulating layer 104 contains, for example, silicon oxide (SiO₂) or the like.

The back-side wiring layer MA includes a plurality of wirings ma. The plurality of wirings ma may contain, for example, aluminum (Al) or the like.

Some of the plurality of wirings ma function as part of the source line SL (FIG. 10). Four of such wirings ma are provided in correspondence with the four memory planes MP0 to MP3 (FIG. 12). The wirings ma are electrically connected to the conductive layers 103, respectively.

Some of the plurality of wirings ma function as the external pad electrodes P_{X}. Such wirings ma are provided in the peripheral area R_{P}. The wirings ma are connected to via contact electrodes CC in the memory cell array layer L_{MCA} in the areas VZ not including the conductive layers 103. Part of the wirings ma is exposed outside the memory die MD through an opening TV provided in the insulating layer 102.

The insulating layer 102 is, for example, a passivation layer made of an insulation material such as polyimide.

### Structure of Memory Cell Array Layer L_{MCA} of Chip C_{M} in Memory Hole Area R_{MH}

As described above with reference to FIG. 12, a plurality of memory blocks BLK arranged in the Y direction are provided in the memory cell array layer L_{MCA}. As illustrated in FIG. 13, an inter-block insulating layer ST such as silicon oxide (SiO₂) is provided between two memory blocks BLK adjacent to each other in the Y direction. A plurality of stacking structures arranged in the Y direction and including a plurality of conductive layers 110 (conductive layers 21) arranged in the Z direction correspond to the plurality of memory blocks BLK.

As illustrated in FIG. 13, for example, each memory block BLK includes the plurality of conductive layers 110 arranged in the Z direction, and a plurality of semiconductor layers 120 (the semiconductor body 210) extending in the Z direction. In addition, a gate insulating film 130 is provided between the plurality of conductive layers 110 and the plurality of semiconductor layers 120.

Each conductive layer 110 has a substantially plate shape extending in the X direction. Each conductive layer 110 may include a multilayer film or the like constituted by a barrier conductive film such as titanium nitride (TiN) and a metal film such as tungsten (W) or molybdenum (Mo). Each conductive layer 110 may contain, for example, polycrystalline silicon or the like containing an impurity such as phosphorus (P) or boron (B). An interlayer insulating layer 111 such as silicon oxide (SiO₂) is provided between the plurality of conductive layers 110 arranged in the Z direction.

Among the plurality of conductive layers 110, one or a plurality of conductive layers 110 positioned uppermost function as the gate electrode of the source-side selection transistor STS (FIG. 10) and the source-side selection gate line SGS (refer to FIG. 13). These plurality of conductive layers 110 are electrically independent for each memory block BLK.

A plurality of conductive layers 110 positioned further downward function as the gate electrodes of the memory cells MC (FIG. 10) and the word lines WL. These plurality of conductive layers 110 are each electrically independent for each memory block BLK.

One or a plurality of conductive layers 110 positioned further downward function as the gate electrode of the drain-side selection transistor STD and the drain-side selection gate line SGD. A Y-directional width Y_{SGD} of these plurality of conductive layers 110 is smaller than a Y-directional width Y_{WL} of the conductive layers 110 functioning as the word lines WL. In addition, an inter-string-unit insulating layer SHE such as silicon oxide (SiO₂) is provided between two conductive layers 110 adjacent to each other in the Y direction.

The semiconductor layers 120 are arranged in a predetermined pattern in the X and Y directions. The semiconductor layers 120 each function as a channel region of the plurality of memory cell MC and the selection transistor (STD, STS) included in one memory string MS (FIG. 10). The semiconductor layers 120 contain, for example, polycrystalline silicon (Si) or the like. Each semiconductor layer 120 has a substantially cylindrical shape, and an insulating layer 125 such as silicon oxide is provided at its central portion. The outer peripheral surface of each semiconductor layer 120 is surrounded by a plurality of conductive layers 110 and faces these plurality of conductive layers 110.

A non-illustrated impurity area is provided at the upper end of each semiconductor layer 120. The impurity area is connected to the above-described conductive layer 103 (refer to FIG. 13). The impurity area contains, for example, an N-type impurity such as phosphorus (P) or a P-type impurity such as boron (B).

A non-illustrated impurity area is provided at the lower end of each semiconductor layer 120. The impurity area is connected to the bit line BL through a via contact electrode ch and a via contact electrode Vy. The impurity area contains, for example, an N-type impurity such as phosphorus (P).

Each gate insulating film 130 has a substantially cylindrical shape that covers the outer peripheral surface of the corresponding semiconductor layers 120. Each gate insulating film 130 includes a tunnel insulating film 131, a charge accumulation film 132, and a block insulating film 133 that are stacked between the corresponding semiconductor layer 120 and conductive layer 110. The tunnel insulating film 131 and the block insulating film 133 contain, for example, silicon oxide (SiO₂), silicon oxynitride (SiON), or the like. The charge accumulation film 132 includes, for example, a film that can accumulate electric charge, such as silicon nitride (SiN). The tunnel insulating film 131, the charge accumulation film 132, and the block insulating film 133 have substantially cylindrical shapes and extend in the Z direction along the outer peripheral surface of the semiconductor layers 120 except for a contact portion of the semiconductor layer 120 and the conductive layer 103.

### Structure of Memory Cell Array Layer L_{MCA} of Chip C_{M} in Peripheral Area R_{P}

In the peripheral area R_{P}, as illustrated in FIG. 13, for example, a plurality of via contact electrodes CC are provided in correspondence with the external pad electrodes P_{X}. The plurality of via contact electrodes CC are connected to the external pad electrodes P_{X} at their upper ends.

### Structure of via Contact Electrode Layer CH

A plurality of via contact electrodes ch included in the via contact electrode layer CH are electrically connected to, for example, at least one of components in the memory cell array layer L_{MCA} and components in the chip C_{P}.

The via contact electrode layer CH includes a plurality of via contact electrodes ch as a plurality of wirings. The plurality of via contact electrodes ch may include, for example, a multilayer film or the like constituted by a barrier conductive film such as titanium nitride (TiN) and a metal film such as tungsten (W). The via contact electrodes ch are provided in correspondence with the plurality of semiconductor layers 120 and connected to the lower ends of the plurality of semiconductor layers 120.

### Structures of Wiring Layers M0 and M1 of Chip C_{M}

A plurality of wirings included in the wiring layers M0 and M1 are electrically connected to, for example, at least one of components in the memory cell array layer L_{MCA} and components in the chip C_{P}.

The wiring layer M0 includes a plurality of wirings m0. The plurality of wirings m0 may include, for example, a multilayer film or the like constituted by a barrier conductive film such as titanium nitride (TiN), tantalum nitride (TaN), or a multilayer film of tantalum nitride (TaN) and tantalum (Ta), and a metal film such as copper (Cu). Note that some of the plurality of wirings m0 function as the bit lines BL. The bit lines BL are arranged in the X direction and extend in the Y direction as illustrated in FIG. 7, for example.

As illustrated in FIG. 5, for example, the wiring layer M1 includes a plurality of wirings m1. The plurality of wirings m1 may include, for example, a multilayer film or the like constituted by a barrier conductive film such as titanium nitride (TiN) and a metal film such as tungsten (W).

### Structure of Chip Bonding Electrode Layer MB

A plurality of wirings included in the chip bonding electrode layer MB are electrically connected to, for example, at least one of components in the memory cell array layer L_{MCA} and components in the chip C_{P}.

The chip bonding electrode layer MB includes the plurality of bonding electrodes P_{I1} (bonding pads). The plurality of bonding electrodes P_{I1} may include, for example, a multilayer film or the like constituted by a barrier conductive film p_{I1B} such as titanium nitride (TiN), tantalum nitride (TaN), or a multilayer film of tantalum nitride (TaN) and tantalum (Ta), and a metal film p_{I1M} such as copper (Cu).

### Structure of Chip C_{P}

As illustrated in FIG. 13, for example, the chip C_{P} includes a semiconductor substrate 200, an electrode layer GC provided above the semiconductor substrate 200, wiring layers D0, D1, D2, D3, and D4 provided above the electrode layer GC, and a chip bonding electrode layer DB provided above the wiring layers D0, D1, D2, D3, and D4.

### Structure of Semiconductor Substrate 200 of Chip C_{P}

The semiconductor substrate 200 contains, for example, a P-type silicon (Si) containing a P-type impurity such as boron (B). For example, an N-type well area 200N containing an N-type impurity such as phosphorus (P), a P-type well area 200P containing a P-type impurity such as boron (B), a semiconductor substrate area 200S in which the N-type well area 200N and the P-type well area 200P are not provided, and an insulation area STI are provided on the front surface of the semiconductor substrate 200. Part of the P-type well area 200P is provided in the semiconductor substrate area 200S, and part of the P-type well area 200P is provided in the N-type well area 200N. The N-type well area 200N, the P-type well area 200P provided in the N-type well area 200N and the semiconductor substrate area 200S, and the semiconductor substrate area 200S each function as part of a plurality of transistors Tr constituting the peripheral circuit PC, a plurality of capacitors, and the like. Note that some of the plurality of transistors Tr function as a word line switch WLSW and a selection gate line switch SGSW.

### Structure of Electrode Layer GC of Chip C_{P}

The electrode layer GC is provided on the upper surface of the semiconductor substrate 200 with an insulating layer 200G interposed therebetween. The electrode layer GC includes a plurality of electrodes gc facing the front surface of the semiconductor substrate 200. The areas of the semiconductor substrate 200 and the plurality of electrodes gc included in the electrode layer GC are each connected to a via contact electrode CS.

The N-type well area 200N, the P-type well area 200P provided in the N-type well area 200N and the semiconductor substrate area 200S, and the semiconductor substrate area 200S in the semiconductor substrate 200 function, respectively, as channel regions of the plurality of transistors Tr constituting the peripheral circuit PC, one electrodes of the plurality of capacitors, and the like.

The plurality of electrodes gc included in the electrode layer GC function as, respectively, gate electrodes of the plurality of transistors Tr constituting the peripheral circuit PC, the other electrodes of the plurality of capacitors, and the like.

Each via contact electrode CS extends in the Z direction and is connected to the upper surface of the semiconductor substrate 200 or the corresponding electrode gc at its lower end. An impurity area containing an N-type impurity or a P-type impurity is provided at a connection portion of each via contact electrode CS and the semiconductor substrate 200. Each via contact electrode CS may include, for example, a multilayer film or the like constituted by a barrier conductive film such as titanium nitride (TiN) and a metal film such as tungsten (W).

### Structures of Wiring Layers D0, D1, D2, D3, and D4 of Chip C_{P}

As illustrated in FIG. 5, for example, a plurality of connection portions and a plurality of wirings included in D0, D1, D2, D3, and D4 are electrically connected to, for example, at least one of components in the memory cell array layer L_{MCA} and components in the chip C_{P}.

The wiring layers D0, D1, and D2 include a plurality of connection portions d0, d1, and d2, respectively, and a plurality of wirings. The plurality of connection portions d0, d1, and d2 and the plurality of wirings may include, for example, a multilayer film or the like constituted by a barrier conductive film such as titanium nitride (TiN) and a metal film such as tungsten (W).

The wiring layers D3 and D4 include a plurality of connection portions d3 and d4, respectively, and a plurality of wirings. The plurality of connection portions d3 and d4 and the plurality of wirings may include, for example, a multilayer film or the like constituted by a barrier conductive film such as titanium nitride (TiN), tantalum nitride (TaN), or a multilayer film of tantalum nitride (TaN) and tantalum (Ta), and a metal film such as copper (Cu).

### Configuration of Chip C_{M}

The configuration of the chip C_{M} will be described below. Among staircase structures of a first configuration example and a second configuration example, the staircase structure of the first configuration example will be described below. However, the configuration of the chip C_{M} described below is also applicable to the staircase structure of the second configuration example.

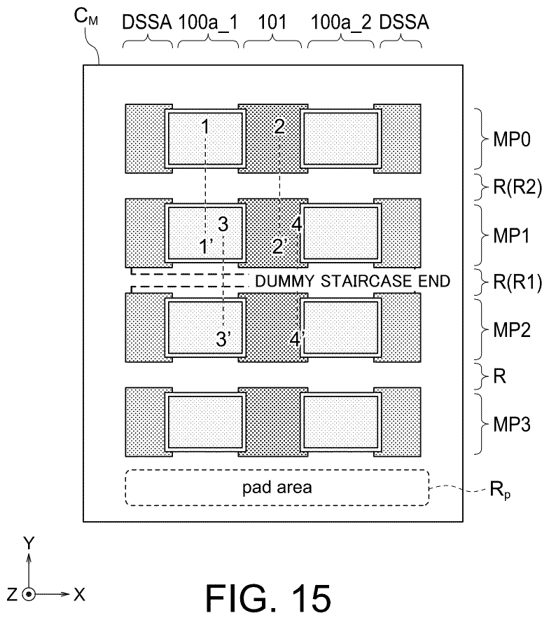

FIG. 15 is a plan view illustrating an example of the configuration of the chip C_{M} according to the first embodiment.

The chip C_{M} includes a plurality of memory planes MP and a pad area Rp. In the example illustrated in FIG. 15, four memory planes MP are illustrated.

Each memory plane MP is a unit that performs write operation, read operation, and erase operation. Each memory plane MP includes one or more blocks BLK.

Each memory plane MP includes the connection area 101, the memory cell areas 100a_1 and 100a_2, and a plurality of dummy staircase areas DSSA.

The connection area 101 is provided at a central portion of the memory plane MP in the X direction. The four memory planes are denoted by MP0, MP1, MP2, and MP3, respectively, in order of increasing distance from the pad area Rp. The dummy staircase areas DSSA are formed on the respective sides in each memory plane MP in the X direction. In addition, dummy staircases are formed on sides facing each other in the Y direction in the memory planes MP1 and MP2. Dummy staircase ends are illustrated with dashed and single-dotted lines. Note that a dummy staircase may or may not be formed on the positive Y side of the memory plane MP0. A dummy staircase may or may not be formed on the negative Y side of the memory plane MP3.

An area R between two memory planes MP is an area that divides the memory planes. The area R includes a first area R1 and a second area R2. The first area R1 is part of a plurality of areas R between the two memory planes MP. The second area R2 is an area that is included in the area R and different from the first area R1.

A plurality of external pad electrodes Px are provided in the pad area Rp.

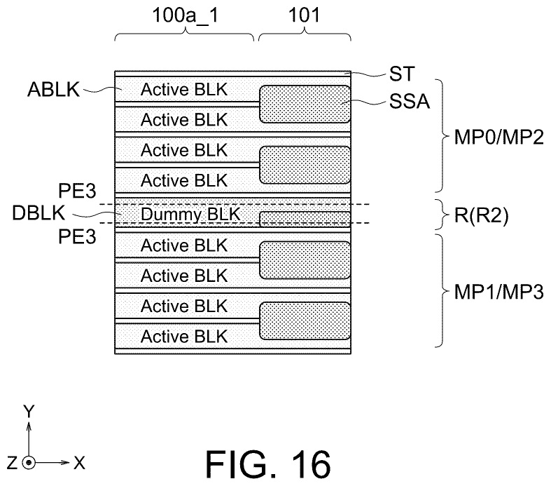

FIG. 16 is a plan view illustrating an example of the configuration of the memory cell area 100a_1 and the connection area 101 according to the first embodiment. FIG. 16 illustrates a structure around the second area R2.

Each memory plane MP includes one or more blocks BLK. A plurality of blocks BLK are arranged in the Y direction. An active block ABLK is a block BLK used for data storage. A dummy block DBLK is a block BLK not used for data storage. In the example illustrated in FIG. 16, a dummy block DBLK is disposed between two active blocks ABLK. One or a plurality of dummy blocks DBLK may be provided. For example, a dummy block DBLK is formed between the memory planes MP0 and MP1 and between the memory planes MP2 and MP3. Each dummy block DBLK may include the staircase area SSA.

An area PE3 indicates an area in which the source line SL (a first layer SL1 and a second layer SL2) is disconnected. In other words, the area PE3 is an area that divides the memory planes MP. The first layer SL1 and the second layer SL2 are, for example, collectively disconnected in the area PE3. The area PE3 is disposed in the dummy block DBLK sandwiched between the two active blocks ABLK.

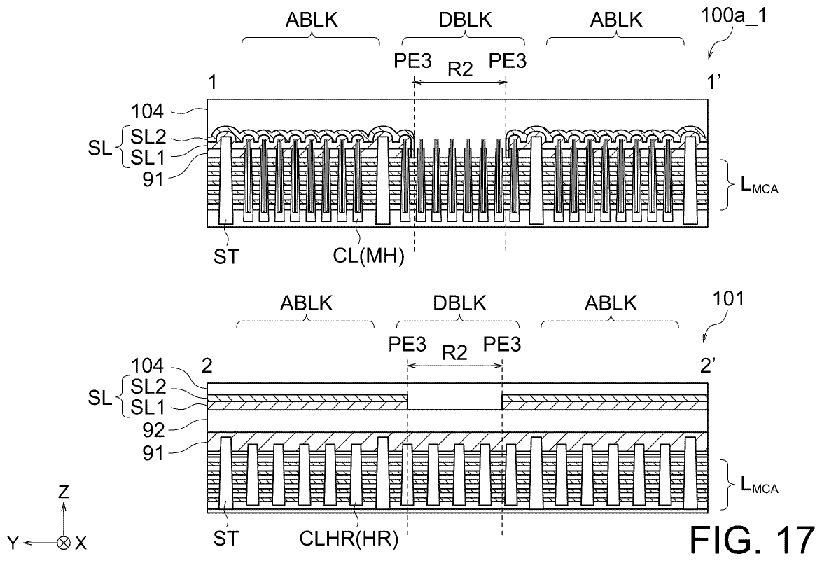

FIG. 17 is a cross sectional view illustrating an example of the configuration of the memory cell area 100a_1 and the connection area 101 according to the first embodiment. The upper part of FIG. 17 illustrates a cross sectional view along line 1-1′ in FIG. 15. The lower part of FIG. 17 illustrates a cross sectional view along line 2-2′ in FIG. 15. In other words, FIG. 17 illustrates structures around the second area R2.

Each block BLK includes a plurality of columnar portions CL (memory holes MH or memory pillars). The columnar portions CL extend in the Z direction.

A source layer SL is electrically connected to one end of each of the plurality of columnar portions CL included in the memory planes MP. The first layer SL1 contains, for example, polysilicon. The second layer SL contains, for example, tungsten (W). Each columnar portion CL contacts the source layer SL at its end face. The source layer SL is disconnected in the second area R2. Accordingly, the memory planes MP are divided.

The semiconductor storage device 100 further includes a semiconductor layer 91, an insulating layer 92, and a dummy block DBLK.

The semiconductor layer 91 is provided on the memory cell array layer L_{MCA}. The semiconductor layer 91 contains, for example, polysilicon.

The insulating layer 92 is provided on the semiconductor layer 91 in the connection area 101. The insulating layer 92 includes, for example, a dTEOS film.

The dummy block DBLK is provided in the second area R2. The dummy block DBLK is provided in correspondence with the cycle of the active blocks ABLK of the two memory planes MP adjacent to the area R.

As illustrated in FIG. 17, the blocks BLK are arranged in the Y direction. Each memory plane MP includes a plurality of active blocks ABLK that share the source line SL. Since the source line SL is disconnected at the dummy block DBLK, the memory planes MP are divided. In this example, the memory planes MP0 and MP1 are divided by the dummy block DBLK. In other words, the memory planes MP are divided such that the first layer SL1 and the second layer SL2 are disconnected while the periodicity of the memory cell array MCA is maintained. Influence on size is small because dummying involves one or a plurality of units of fingers. Note that the source line SL is disconnected by, for example, backside processing.

The via contact electrodes cc may be provided in the second area R2.

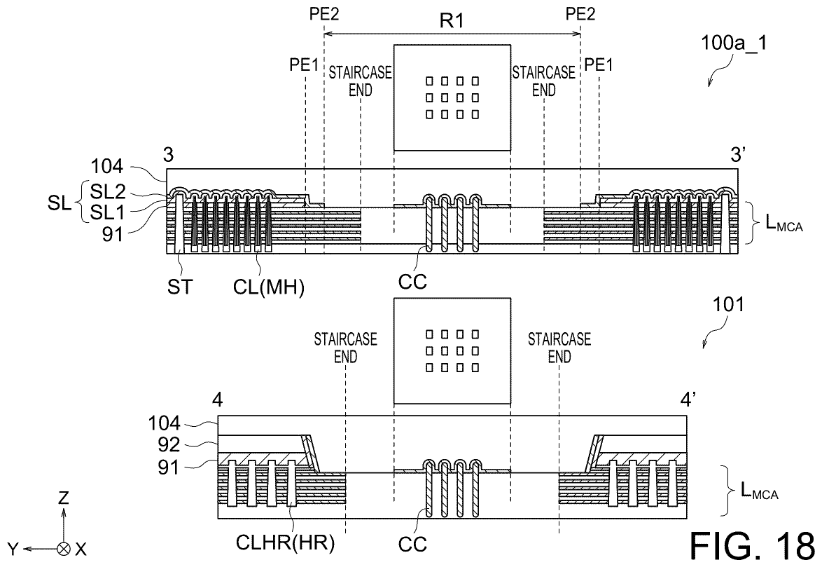

FIG. 18 is a cross sectional view illustrating an example of the configuration of the memory cell area 100a_1 and the connection area 101 according to the first embodiment. The upper part of FIG. 18 illustrates a cross sectional view along line 3-3′ in FIG. 15. The lower part of FIG. 18 illustrates a cross sectional view along line 4-4′ in FIG. 15. In addition, the planar structure of the via contact electrodes CC is also illustrated. In other words, FIG. 18 illustrates structures around the first area R1.

As illustrated in FIG. 18, the memory planes MP are divided by dummy staircase portions. In this example, the memory planes MP1 and MP2 are divided by dummy staircase portions. An insulating layer is embedded and the via contact electrodes CC are provided between dummy staircase portions formed in the memory planes MP1 and MP2. A stacked body in which SiO₂ (insulating layer) and SiN (sacrifice layer) are alternately stacked is removed and another insulating layer is embedded again to form the via contact electrodes CC. Alternatively, the stacked body in which SiO₂ (insulating layer) and SiN (sacrifice layer) are alternately stacked may remain between the dummy staircase portions, and the via contact electrodes CC may be provided so as to penetrate the stacked body.

An area PE1 indicates an area in which the first layer SL1 is disconnected. An area PE2 indicates an area in which the second layer SL2 is disconnected.

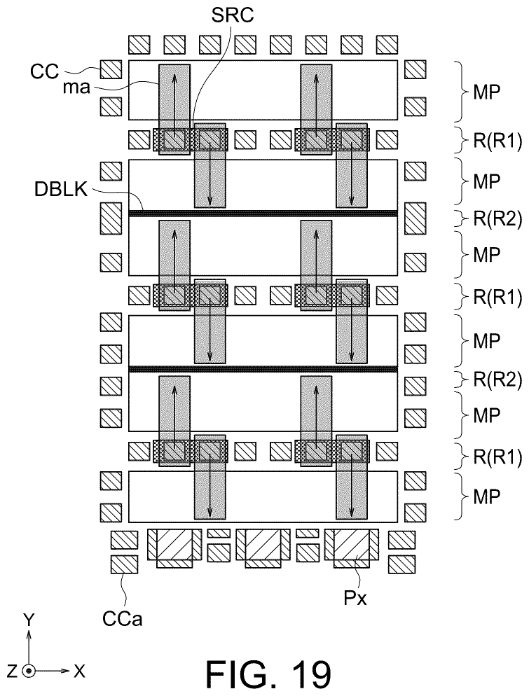

The via contact electrodes CC are provided in the first area R1. The via contact electrodes CC extend in the Z direction. The via contact electrodes CC are electrically connected to one memory plane MP. The via contact electrodes CC, are electrically connected to one memory plane MP through, for example, wirings ma provided along an opening portion (not illustrated) of the insulating layer 104 provided on the via contact electrodes CC (refer to FIG. 19). The via contact electrodes CC here may include not only columnar portions but also planner electrodes connected to a plurality of columnar portions. In other words, the via contact electrodes CC may include rectangular electrodes.

FIG. 19 is a plan view illustrating an example of the configuration of the chip C_{M} according to the first embodiment. Note that FIG. 19 illustrates part of the chip C_{M}.

The six memory planes mp are disposed in a 1×6 configuration.

The area R (first area R1) between the uppermost memory plane MP and the second uppermost memory plane MP on the sheet is partitioned by dummy staircase portions. The via contact electrodes CC are provided at the dummy staircase portions. The area R (second area R2) between the second uppermost memory plane and the third uppermost memory plane MP is partitioned by the dummy block DBLK.

In the example illustrated in FIG. 19, two dummy blocks DBLK are disposed to allow reduction in the chip size by the equivalent of two columns of gaps between the memory planes MP.

A cell source driver circuit SRC is formed in the chip C_{P}. The via contact electrodes CC are connected to the cell source driver circuit SRC. The via contact electrodes CC are connected to the source line SL of the memory planes MP through the wirings ma. The cell source driver circuit SRC corresponds to, for example, any of the transistors Tr. In this manner, the cell source driver circuit SRC supplies source voltage to the source line SL through the via contact electrodes CC. The source voltage may be supplied to the cell source driver circuit SRC from the external pad electrodes Px through wirings on the chip C_{M} side, such as the wirings ma.

Note that, as illustrated in FIG. 19, via contact electrodes CCa may be provided in an area outside the memory planes MP and outside the external pad electrodes Px. With the via contact electrodes CCa, it is possible to compensate reduction in the number of via contact electrodes CC due to reduction in the number of gaps between memory planes MP. Note that the via contact electrodes CCa do not necessarily need to be provided. The via contact electrodes CCa here may include not only columnar portions but also planner electrodes connected to a plurality of columnar portions. In other words, the via contact electrodes CCa may include rectangular electrodes.

Wirings inside the chip C_{P} may be extended in the Y direction from the external pad electrodes Px through the via contact electrodes CCa and used in place of the wirings ma to supply voltage to the cell source driver circuit SRC. The wirings of the chip C_{P} are, for example, the connection portions d3 and d4 illustrated in FIGS. 13 and 14.

As described above, according to the first embodiment, the via contact electrodes CC are provided in the first area R1 that is part of a plurality of areas R between two memory planes MP. More specifically, the via contact electrodes CC are not provided in the second area R2 that is included in the plurality of areas R between the two memory planes MP and different from the first area R1. Accordingly, the chip size can be reduced.

Note that the dummy block DBLK may not be subjected to a replacing process that replaces sacrifice films with the conductive layers 21. In other words, the dummy block DBLK may include a stacked body constituted by alternately stacking a plurality of insulating layers 22 and a plurality of sacrifice films in the Z-axis direction.

The first embodiment is not limited to the staircase structures illustrated in FIGS. 5 to 8B, but the staircase structure illustrated in FIG. 2 is also applicable.

In the first embodiment, as illustrated in FIG. 17, the first layer SL1 and the second layer are both disconnected in the area PE3. However, the present invention is not limited thereto, the position of disconnection may be offset between the first layer SL1 and the second layer SL2.

In the first embodiment, as illustrated in FIG. 18, the first layer SL1 is disconnected in the area PE1, and the second layer SL2 is disconnected in the area PE2. However, the present invention is not limited thereto, and the first layer SL1 and the second layer SL2 may be disconnected at substantially the same positions. In other words, the first layer SL1 and the second layer SL2 may be collectively removed as in the area PE3 illustrated in FIG. 17.

### Comparative Example

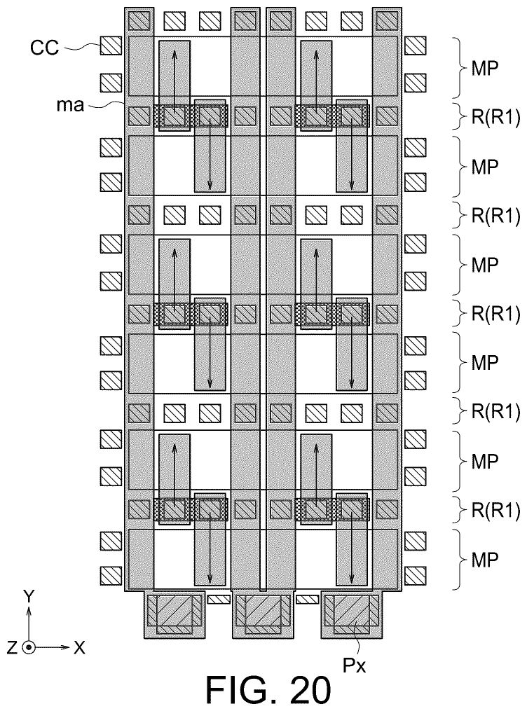

FIG. 20 is a plan view illustrating an example of the configuration of the chip C_{M} according to a comparative example. The comparative example is different from the first embodiment in that the memory planes MP are not divided by the dummy block DBLK.

Note that FIG. 20 illustrates the wirings ma connecting the external pad electrodes Px to the via contact electrodes CC other than the via contact electrodes CC of the cell source driver circuit SRC, which are omitted in FIG. 19.

As illustrated in FIG. 18, all areas R between the memory planes MP are divided by dummy staircase portions. In this case, the cell periodicity between the memory planes MP is disrupted. Furthermore, disposition of the via contact electrodes CC results in increase in chip area.

However, in the first embodiment, dummy staircase portions are not provided, and the memory planes MP are divided by the dummy block DBLK. Accordingly, disruption of the cell periodicity can be prevented. Moreover, since the via contact electrodes CC are not provided in an area between the two divided memory planes MP, the chip size can be reduced.

### First Modification of First Embodiment

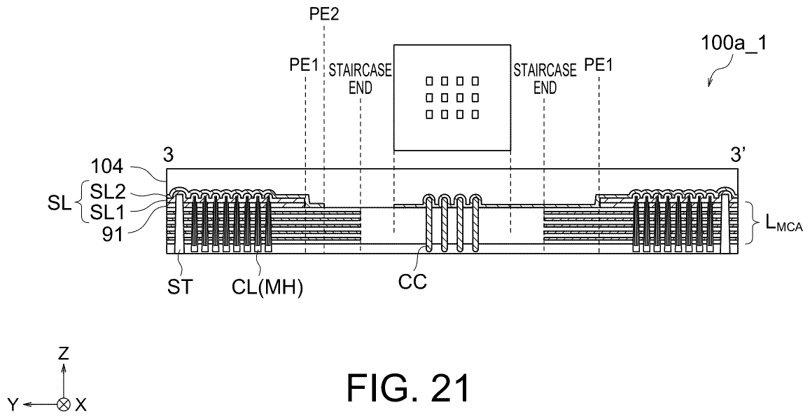

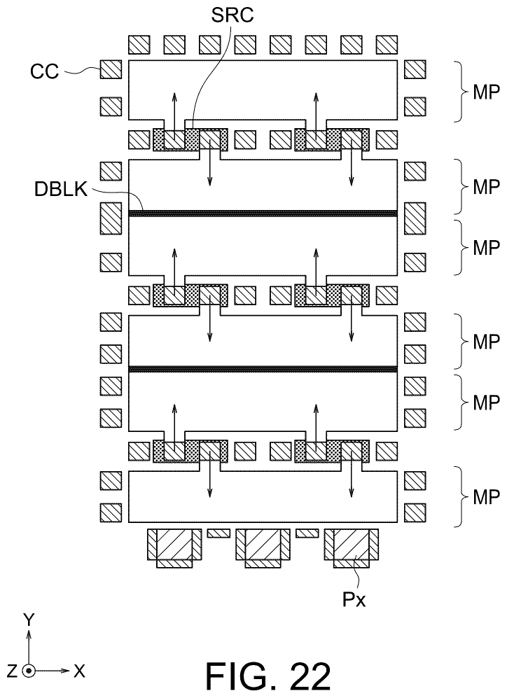

FIG. 21 is a cross sectional view illustrating an example of the configuration of the memory cell area 100a_1 according to a first modification of the first embodiment. FIG. 22 is a plan view illustrating an example of the configuration of the chip C_{M} according to the first modification of the first embodiment. The first modification of the first embodiment is different from the first embodiment in that the memory planes MP and the via contact electrodes CC are electrically connected by the second layer SL2 in place of the wirings ma.

The second layer SL2 extends in the Y direction and is electrically connected to the via contact electrodes CC.

Note that, in one chip C_{M}, connection using the wirings ma and connection using the second layer SL2 may be combined.

As in the first modification of the first embodiment, the memory planes MP and the via contact electrodes CC may be electrically connected by the second layer SL2. The semiconductor storage device 100 according to the first modification of the first embodiment can achieve the same effects as in the first embodiment.

### Second Modification of First Embodiment

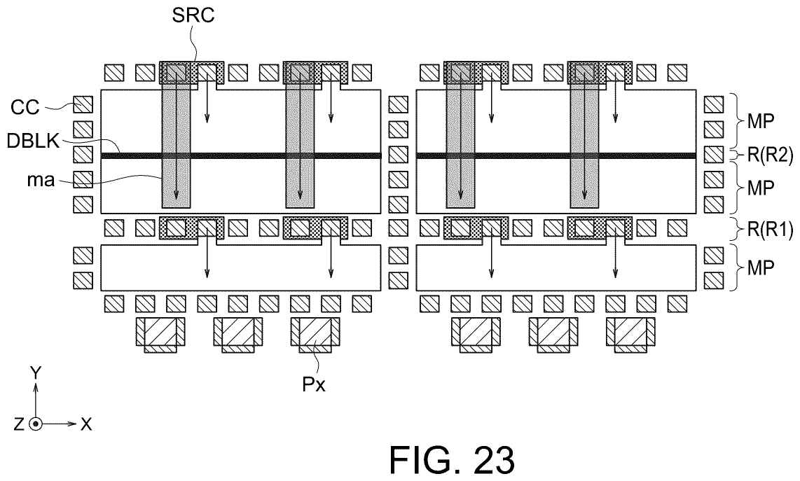

FIG. 23 is a plan view illustrating an example of the configuration of the chip C_{M} according to a second modification of the first embodiment. The second modification of the first embodiment is different from the first embodiment in that the six memory planes MP are disposed in a 2×3 configuration.

The area R between the uppermost memory plane MP and the second uppermost memory plane MP on the sheet is partitioned by a dummy block DBLK. The area R between the second uppermost memory plane and the third uppermost memory plane MP is partitioned by dummy staircase portions. The via contact electrodes CC are provided at the dummy staircase portions.

In the example illustrated in FIG. 23, one dummy block DBLK is disposed to allow reduction in the chip size by the equivalent of one column of gaps between the memory planes MP.

Two via contact electrodes CC electrically connected to two memory planes MP, respectively, adjacent to the second area R2 are provided on one side in a direction (for example, the Y direction) in which the two memory planes MP are arranged. In other words, two via contact electrodes CC of the cell source driver circuit SRC, which are electrically connected to the two memory planes, respectively, divided by the dummy block DBLK are positioned in the Y direction relative to the two memory plane MP.

The memory plane MP that is farther from the two via contact electrodes CC is electrically connected to one of the two via contact electrodes CC through the wirings ma.

The memory plane MP that is closer to the via contact electrodes CC of the cell source driver circuit SRC is electrically connected to the via contact electrodes CC of the cell source driver circuit SRC through the second layer SL2 as described above in the first modification of the first embodiment. Note that the memory plane MP closer to the via contact electrodes CC of the cell source driver circuit SRC may be electrically connected to the via contact electrodes CC of the cell source driver circuit SRC through the wirings ma.

Note that, in FIG. 23, the memory plane MP closest to the external pad electrodes Px is electrically connected to the via contact electrodes CC of the cell source driver circuit SRC through the second layer SL2 as described above in the first modification of the first embodiment. Note that the memory plane MP closest to the external pad electrodes Px may be electrically connected to the via contact electrodes CC of the cell source driver circuit SRC through the wirings ma.

As in the second modification of the first embodiment, the six memory planes MP may be disposed in a 2×3 configuration. The semiconductor storage device 100 according to the first modification of the first embodiment can achieve the same effects as in the first embodiment.

### Third Modification of First Embodiment

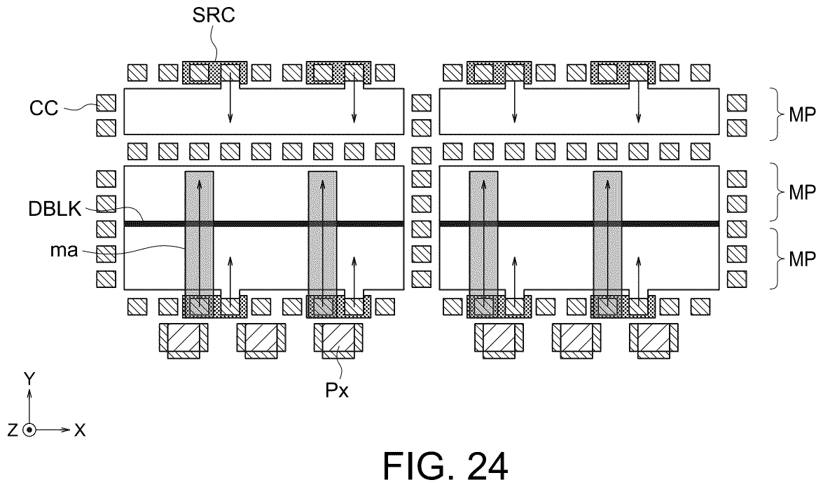

FIG. 24 is a plan view illustrating an example of the configuration of the chip C_{M} according to a third modification of the first embodiment. In the third modification of the first embodiment, the position at which the dummy block DBLK is provided is different from that in the second modification of the first embodiment.

The area R between the uppermost memory plane MP and the second uppermost memory plane MP on the sheet is partitioned by dummy staircase portions. The via contact electrodes CC are provided at the dummy staircase portions. The area R between the second uppermost memory plane and the third uppermost memory plane MP is partitioned by the dummy block DBLK.

As in the third modification of the first embodiment, the position at which the dummy block DBLK is provided may be changed. The semiconductor storage device 100 according to the third modification of the first embodiment can achieve the same effects as in the second modification of the first embodiment.

### Fourth Modification of First Embodiment

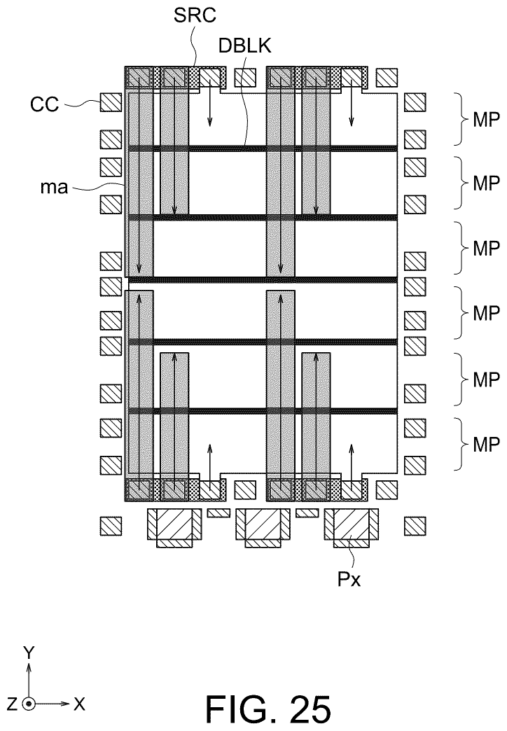

FIG. 25 is a plan view illustrating an example of the configuration of the chip C_{M} according to a fourth modification of the first embodiment. In the fourth modification of the first embodiment, the number of deleted gaps between memory planes MP is different from that in the first embodiment.

Six memory planes mp are disposed in a 1×6 configuration.

In the example illustrated in FIG. 25, five dummy blocks DBLK are disposed to allow reduction in the chip size by the equivalent of five columns of gaps between the memory planes MP.

As in the fourth modification of the first embodiment, the number of deleted gaps between the memory planes MP may be changed. The semiconductor storage device 100 according to the fourth modification of the first embodiment can achieve the same effects as in the first embodiment.

### Fifth Modification of First Embodiment

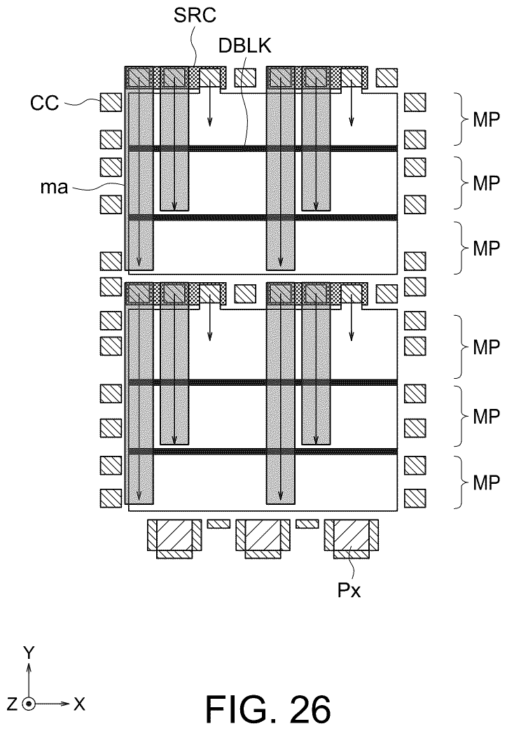

FIG. 26 is a plan view illustrating an example of the configuration of the chip C_{M} according to a fifth modification of the first embodiment. In the fifth modification of the first embodiment, the number of deleted gaps between memory planes MP is different from the first embodiment.

In the example illustrated in FIG. 26, four dummy blocks DBLK are disposed to allow reduction in the chip size by the equivalent of four columns of gaps between the memory planes MP.

As in the fifth modification of the first embodiment, the number of deleted gaps between the memory planes MP may be changed. The semiconductor storage device 100 according to the fifth modification of the first embodiment can achieve the same effects as in the first embodiment.

### Sixth Modification of First Embodiment

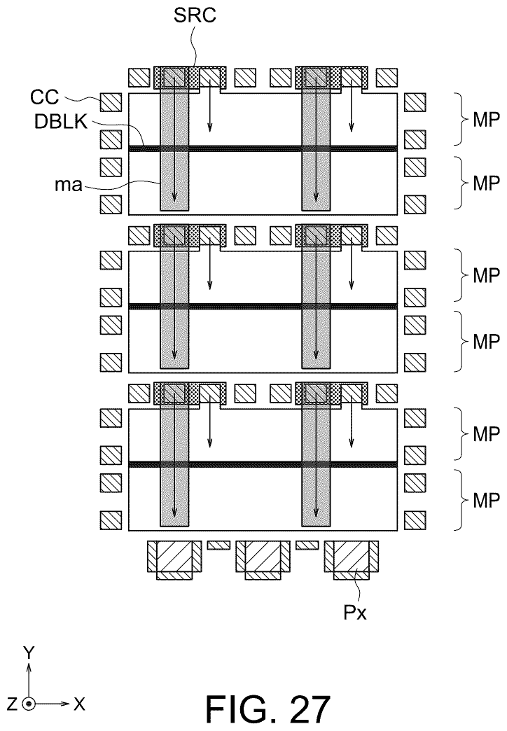

FIG. 27 is a plan view illustrating an example of the configuration of the chip C_{M} according to a sixth modification of the first embodiment. In the sixth modification of the first embodiment, the number of deleted gaps between memory planes MP is different from the first embodiment.

In the example illustrated in FIG. 27, three dummy blocks DBLK are disposed to allow reduction in the chip size by the equivalent of three columns of gaps between the memory planes MP.

As in the sixth modification of the first embodiment, the number of deleted gaps between the memory planes MP may be changed. The semiconductor storage device 100 according to the sixth modification of the first embodiment can achieve the same effects as in the first embodiment.

### Seventh Modification of First Embodiment

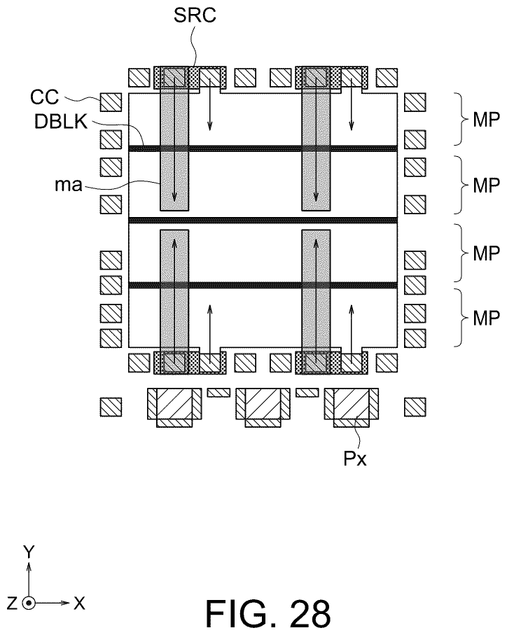

FIG. 28 is a plan view illustrating an example of the configuration of the chip C_{M} according to a seventh modification of the first embodiment. In the seventh modification of the first embodiment, the number of deleted gaps between memory planes MP is different from the first embodiment.

Four memory planes MP are disposed in a 1×4 configuration.

In the example illustrated in FIG. 28, three dummy blocks DBLK are disposed to allow reduction in the chip size by the equivalent of three columns of gaps between the memory planes MP.

As in the seventh modification of the first embodiment, the number of deleted gaps between the memory planes MP may be changed. The semiconductor storage device 100 according to the seventh modification of the first embodiment can achieve the same effects as in the first embodiment.

### Eighth Modification of First Embodiment

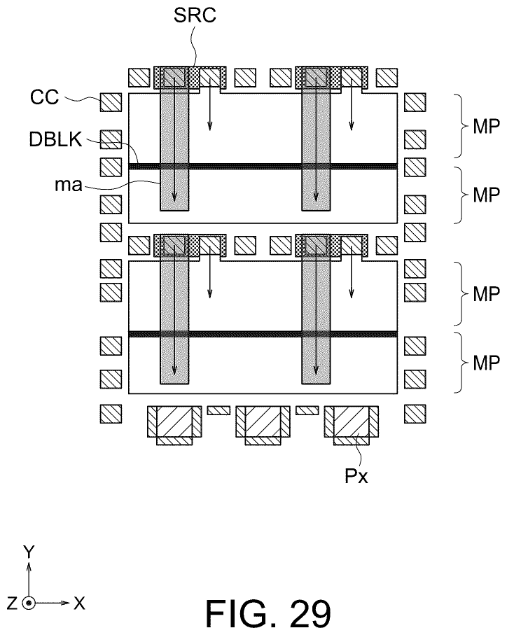

FIG. 29 is a plan view illustrating an example of the configuration of the chip C_{M} according to an eighth modification of the first embodiment. In the eighth modification of the first embodiment, the number of deleted gaps between memory planes MP is different from the first embodiment.

### Four Memory Planes Mp Are Disposed in a 1×4 Configuration.

In the example illustrated in FIG. 29, two dummy blocks DBLK are disposed to allow reduction in the chip size by the equivalent of two columns of gaps between the memory planes MP.

As in the eighth modification of the first embodiment, the number of deleted gaps between the memory planes MP may be changed. The semiconductor storage device 100 according to the seventh modification of the first embodiment can achieve the same effects as in the first embodiment.

### Second Embodiment

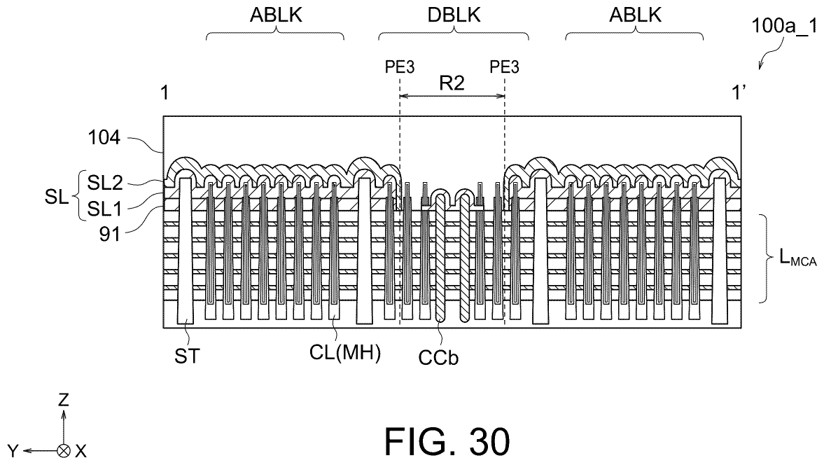

FIG. 30 is a cross sectional view illustrating an example of the configuration of the memory cell area 100a_1 according to a second embodiment. The second embodiment is different from the first embodiment in that via contact electrodes are provided in a dummy block DBLK.

The semiconductor storage device 100 further includes via contact electrodes CCb. The via contact electrodes CCb are provided in an area where the columnar portions CL of the dummy block DBLK are provided in the second area R2. In other words, the via contact electrodes CCb are provided in place of dummy columnar portions CL (memory holes MH) in the memory cell area 100a_1 of the dummy block DBLK. The via contact electrodes CCb extend in the Z direction. With the via contact electrodes CCb, it is possible to compensate reduction in the number of via contact electrodes CC due to reduction in the number of gaps between memory planes MP. The via contact electrodes CCb here may include not only columnar portions but also planner electrodes connected to a plurality of columnar portions. In other words, the via contact electrodes CCb may include rectangular electrodes. Note that the area of each via contact electrode CCb when viewed from top may be smaller than that of each via contact electrode CC in FIG. 18.

Note that the via contact electrodes CCb is not limited to the memory cell area 100a_1 of the dummy block DBLK but may be provided in place of other dummy columnar portions CL (memory holes MH).

As in the second embodiment, the via contact electrodes CCb may be provided in an area where the columnar portions CL of the dummy block DBLK are provided. The semiconductor storage device 100 according to the second embodiment can achieve the same effects as in the first embodiment.

### Third Embodiment

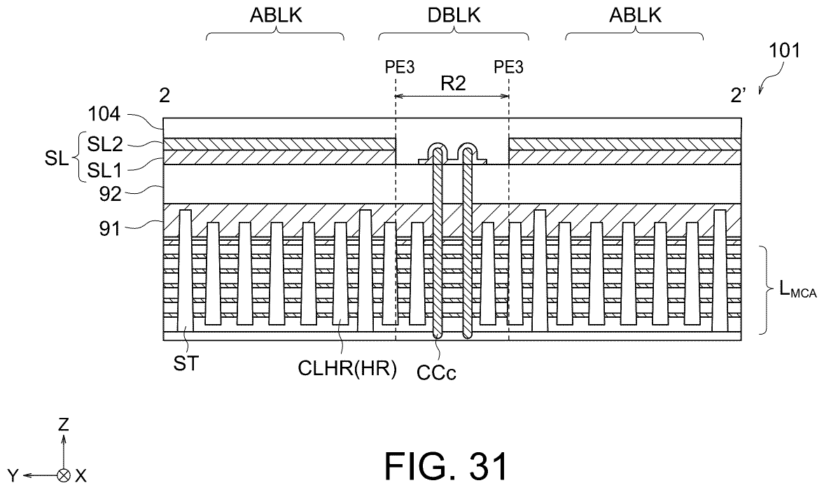

FIG. 31 is a cross sectional view illustrating an example of the configuration of the connection area 101 according to a third embodiment. The third embodiment is different from the first embodiment in that via contact electrodes are provided in a dummy block DBLK.

The semiconductor storage device 100 further includes via contact electrodes CCc. The via contact electrodes CCc are provided in the staircase area SSA of the dummy block DBLK in the second area R2. In other words, the via contact electrodes CCc are provided in the connection area 101 of the dummy block DBLK. The via contact electrodes CCc extend in the Z direction. With the via contact electrodes CCc, it is possible to compensate reduction in the number of via contact electrodes CC due to reduction in the number of gaps between memory planes MP. For example, in FIG. 8A, there is a place where no conductive layers 21 are provided at the central portion. The via contact electrodes CCc are preferably disposed at such a place. The via contact electrodes CCc here may include not only columnar portions but also planner electrodes connected to a plurality of columnar portions. In other words, the via contact electrodes CCc may include rectangular electrodes. Note that the area of each via contact electrode CCc when viewed from top may be smaller than that of each via contact electrode CC in FIG. 18.

As in the third embodiment, the via contact electrodes CCc may be provided in the staircase area SSA of the dummy block DBLK. The semiconductor storage device 100 according to the third embodiment can achieve the same effects as in the first embodiment.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor storage device comprising:
a plurality of memory planes each including one or more blocks; and
a first columnar electrode provided in a first area and extending in a first direction substantially perpendicular to the memory planes, the first area being part of a plurality of areas between two of the memory planes,
wherein the first columnar electrode is not provided in a second area that is included in the plurality of areas between the two memory planes and different from the first area.

2. The semiconductor storage device according to claim 1, wherein the first columnar electrode is electrically connected to one of the memory planes.

3. The semiconductor storage device according to claim 1, further comprising a dummy block provided in the second area and corresponding to a cycle of the blocks of the two memory planes adjacent to the area.

4. The semiconductor storage device according to claim 3, further comprising a second columnar electrode provided in an area where memory pillars of the dummy block are provided in the second area, the second columnar electrode extending in the first direction.

5. The semiconductor storage device according to claim 3, further comprising a third columnar electrode provided in a staircase area of the dummy block in the second area and extending in the first direction.

6. The semiconductor storage device according to claim 5, wherein the staircase area is provided at a central portion of the dummy block.

7. The semiconductor storage device according to claim 1, wherein
each of the blocks includes a plurality of memory pillars extending in the first direction,
the semiconductor storage device further comprises a first wiring electrically connected to one end of each of the plurality of memory pillars included in the memory planes, and
the first wiring is disconnected in the second area.

8. The semiconductor storage device according to claim 1, wherein
two of the first columnar electrodes electrically connected to respective ones of two of the memory planes adjacent to the second area are provided on one side in a direction in which the two memory planes are arranged, and
the memory plane that is farther from the two first columnar electrodes is electrically connected to one of the two first columnar electrodes through a second wiring.

9. The semiconductor storage device according to claim 1, further comprising:
a first chip on which the plurality of memory planes are provided; and
a second chip bonded to the first chip and provided with a control circuit configured to control the memory planes.

10. The semiconductor storage device according to claim 1, wherein
each of the blocks includes a plurality of memory pillars extending in the first direction,
the semiconductor storage device further comprises a first wiring electrically connected to one end of each of the plurality of memory pillars included in the memory planes, and
the memory pillar includes a semiconductor layer contacting the first wiring at an end face.
